(19) United States
(12) Patent Application Publication
(10) Pub. No.: US 2026/0032918 A1
(43) Pub. Date: Jan. 29, 2026

(54) SEMICONDUCTOR DEVICE INCLUDING DIELECTRIC STRUCTURE INCLUDING FERROELECTRIC LAYER AND DIELECTRIC LAYER

(71) Applicant: SK hynix Inc., Icheon-si Gyeonggi-do (KR)

(72) Inventors: Won Tae KOO, Icheon-si Gyeonggi-do (KR); Dong Ik SUH, Icheon-si Gyeonggi-do (KR)

(73) Assignee: SK hynix Inc., Icheon-si Gyeonggi-do (KR)

(21) Appl. No.: 19/349,278

(22) Filed: Oct. 3, 2025

Related U.S. Application Data
(62) Division of application No. 18/071,256, filed on Nov. 29, 2022.

(30) Foreign Application Priority Data
Jul. 12, 2022 (KR) 10-2022-0085972

(51) Int. Cl. H10B 53/30

(52) U.S. Cl. CPC H10B 53/30

(57) ABSTRACT

A semiconductor device according to an embodiment includes a substrate including a channel region, a gate dielectric structure disposed over the channel region, and a gate electrode disposed over the gate dielectric structure. The gate dielectric structure includes a barrier dielectric layer and a gate dielectric layer that are connected in series to each other. The barrier dielectric layer includes a ferroelectric material. The gate dielectric layer includes a non-ferroelectric material. The gate dielectric structure exhibits non-ferroelectric property.

### CROSS-REFERENCE TO RELATED APPLICATIONS

The present application a divisional application of a U.S. patent application Ser. No. 18/071,256 filed on Nov. 29, 2022, which claims priority under 35 U.S.C. 119(a) to Korean Patent Application No. 10-2022-0085972, filed in the Korean Intellectual Property Office on Jul. 12, 2022, which applications are incorporated herein by reference in their entirety.

### BACKGROUND

### 1. Technical Field

The present disclosure generally relates to a semiconductor device and, more particularly, to a semiconductor device including a dielectric structure including a ferroelectric layer and a dielectric layer.

### 2. Related Art

As the feature size of a semiconductor chip decreases, the size of a unit device such as a capacitor device or a transistor device disposed in the semiconductor chip also decreases. However, the capacitance required for a dielectric layer constituting the unit device is required to maintain a predetermined reference value to ensure reliability of device operations. Accordingly, various methods for increasing the capacitance of the dielectric layer applied to the unit device are being studied.

As a representative method of increasing the capacitance of the dielectric layer, a method of applying a high-k material to the dielectric layer of the unit device is used. However, as the trend of decreasing the feature size of the semiconductor chip continues, research to improve the leakage current and breakdown voltage characteristics of the dielectric layer when a high-k material is applied to the dielectric layer is in progress.

### SUMMARY

A semiconductor device according to an embodiment of the present disclosure includes a substrate including a channel region, a gate dielectric structure disposed over the channel region, and a gate electrode disposed over the gate dielectric structure. The gate dielectric structure includes a barrier dielectric layer and a gate dielectric layer that are connected in series to each other. The barrier dielectric layer includes a ferroelectric material. The gate dielectric layer includes a non-ferroelectric material. The gate dielectric structure exhibits non-ferroelectric property.

A semiconductor device according to another embodiment of the present disclosure includes a substrate, an active layer disposed over the substrate, a gate dielectric structure disposed to be adjacent to the active layer, and a gate electrode disposed over the gate dielectric structure. The gate dielectric structure includes a barrier dielectric layer and a gate dielectric layer that are connected in series to each other. The barrier dielectric layer includes a ferroelectric material. The gate dielectric layer includes a non-ferroelectric material.

### BRIEF DESCRIPTION OF THE DRAWINGS

FIG. 1 is a graph schematically illustrating polarization characteristics of a ferroelectric layer.

FIG. 2 is a graph schematically illustrating polarization characteristics of a dielectric layer included in a dielectric structure according to an embodiment of the present disclosure.

FIG. 3 is a view schematically illustrating polarization characteristics of a ferroelectric layer included in a dielectric structure according to an embodiment of the present disclosure.

FIG. 4 is a circuit diagram schematically illustrating an electric circuit configuration of a dielectric structure according to an embodiment of the present disclosure.

FIG. 5 is a cross-sectional view schematically illustrating a semiconductor device according to an embodiment of the present disclosure.

FIG. 6 illustrates graphs schematically illustrating the results of simulating the charge amounts of semiconductor devices according to an applied voltage.

FIG. 7 illustrates graphs schematically illustrating results of simulating leakage currents of semiconductor devices according to applied voltages.

FIG. 8 is a cross-sectional view schematically illustrating a semiconductor device according to another embodiment of the present disclosure.

FIG. 9 is a cross-sectional view schematically illustrating a semiconductor device according to further another embodiment of the present disclosure.

FIG. 10 is a cross-sectional view schematically illustrating a semiconductor device according to further another embodiment of the present disclosure.

FIG. 11 is a cross-sectional view schematically illustrating a semiconductor device according to further another embodiment of the present disclosure.

FIG. 12 is a cross-sectional view schematically illustrating a semiconductor device according to yet another embodiment of the present disclosure.

FIG. 13 is a cross-sectional view schematically illustrating a semiconductor device according to still yet another embodiment of the present disclosure.

FIG. 14A is a plan view schematically illustrating memory cells of an electronic device according to an embodiment of the present disclosure.

FIG. 14B is a cross-sectional view of the memory cells of FIG. 14A taken along line A-A′.

FIG. 14C is a cross-sectional view of the memory cells of FIG. 14A taken along line B-B′.

FIG. 15A is a cross-sectional view schematically illustrating a capacitor of a semiconductor device according to an embodiment of the present disclosure.

FIG. 15B is a cross-sectional view of the semiconductor device of FIG. 15A taken along line I-I′ and shown on the x-y plane.

FIG. 16 is a cross-sectional view schematically illustrating a capacitor of a semiconductor device according to another embodiment of the present disclosure.

FIG. 17A is a cross-sectional view schematically illustrating a capacitor of a semiconductor device according to further another embodiment of the present disclosure.

FIG. 17B is a cross-sectional view of the semiconductor device of FIG. 17A taken along line II-II′ and shown on the x-y plane.

FIG. 18A is a cross-sectional view schematically illustrating a semiconductor device according to further another embodiment of the present disclosure.

FIG. 18B is a cross-sectional view of the semiconductor device of FIG. 18A taken along line III-III′ and shown on the x-y plane.

FIG. 19 is a cross-sectional view schematically illustrating a semiconductor device according to further another embodiment of the present disclosure.

FIG. 20A is a cross-sectional view schematically illustrating a semiconductor device according to further another embodiment of the present disclosure.

FIG. 20B is a cross-sectional view of the semiconductor device of FIG. 20A taken along line IV-IV′ and shown on the x-y plane.

FIG. 21 is a cross-sectional view schematically illustrating a semiconductor device including a gate dielectric structure according to an embodiment of the present disclosure.

FIG. 22A is a cross-sectional view schematically illustrating a semiconductor device according to further another embodiment of the present disclosure.

FIG. 22B is a cross-sectional view of the semiconductor device of FIG. 22A taken along line V-V′ and shown on the x-y plane.

FIG. 23 is a cross-sectional view schematically illustrating a semiconductor device including a gate dielectric structure according to further another embodiment of the present disclosure.

FIG. 24 is a cross-sectional view schematically illustrating a semiconductor device according to further another embodiment of the present disclosure.

FIG. 25 is a cross-sectional view schematically illustrating a semiconductor device according to further another embodiment of the present disclosure.

FIG. 26A is a perspective view schematically illustrating a semiconductor device according to further another embodiment of the present disclosure.

FIG. 26B is a cross-sectional view of the semiconductor device of FIG. 26A taken along line IV-IV′.

FIG. 27A is a perspective view schematically illustrating a semiconductor device according to yet another embodiment of the present disclosure.

FIG. 27B is a cross-sectional view taken along the line V-V′ of the semiconductor device of FIG. 27A.

FIG. 27C is a cross-sectional view taken along the line VI-VI′ of the semiconductor device of FIG. 27A.

FIG. 28A is a perspective view schematically illustrating a semiconductor device according to still yet another embodiment of the present disclosure.

FIG. 28B is a cross-sectional view of the semiconductor device of FIG. 28A taken along the line VII-VII′.

FIG. 28C is a cross-sectional view of the semiconductor device of FIG. 28A taken along the line VIII-VIII′.

### DETAILED DESCRIPTION

Hereinafter, embodiments of the present disclosure will be described in detail with reference to the accompanying drawings. In the drawings, in order to clearly express the components of each device, the sizes of the components, such as width and thickness of the components, are enlarged. The terms used herein may correspond to words selected in consideration of their functions in the embodiments, and the meanings of the terms may be construed to be different according to the ordinary skill in the art to which the embodiments belong. If expressly defined in detail, the terms may be construed according to the definitions. Unless otherwise defined, the terms (including technical and scientific terms) used herein have the same meaning as commonly understood by one of ordinary skill in the art to which the embodiments belong.

In addition, expression of a singular form of a word should be understood to include the plural forms of the word unless clearly used otherwise in the context. It will be understood that the terms “comprise”, “include”, or “have” are intended to specify the presence of a feature, a number, a step, an operation, a component, an element, a part, or combinations thereof, but not used to preclude the presence or possibility of addition one or more other features, numbers, steps, operations, components, elements, parts, or combinations thereof.

According to embodiments of the present disclosure, a semiconductor device may include a dielectric structure disposed between a first electrode and a second electrode that are disposed to be spaced apart from each other. The dielectric structure may include a ferroelectric layer and a dielectric layer that are disposed in series to each other. In this specification, unless otherwise specified, the dielectric layer may refer to a non-ferroelectric layer. As an example, the non-ferroelectric layer may be a paraelectric layer.

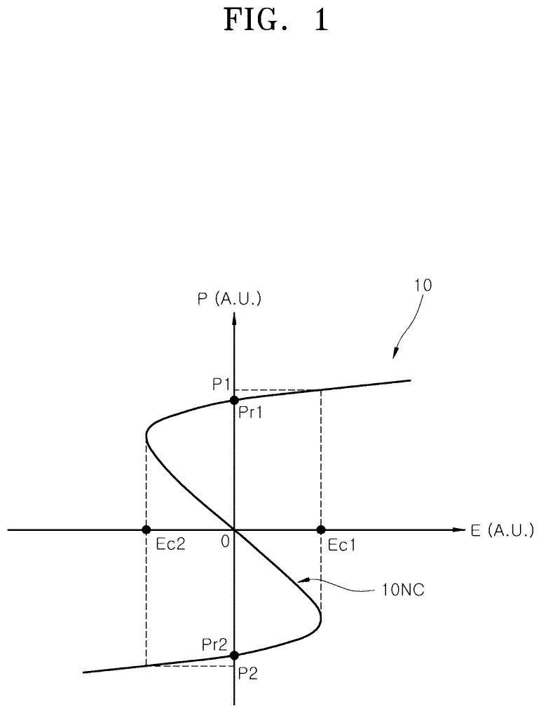

FIG. 1 is a graph schematically illustrating polarization characteristics of a ferroelectric layer. Specifically, FIG. 1 is a graph 10 illustrating the change in polarization of a ferroelectric layer when an electric field E is applied to both ends of the ferroelectric layer. As an example, FIG. 1 may be a graph 10 schematically illustrating the polarization characteristics of the ferroelectric layer, derived from the Landau-Ginzburg-Devonshire (LGD) theory.

Referring to the graph 10 of FIG. 1, the ferroelectric layer may have first and second remanent polarization Pr1 and Pr2 and first and second coercive fields Ec1 and Ec2. The first and second remanent polarization Pr1 and Pr2 may be polarization that is maintained in the ferroelectric layer in a state in which no electric field is applied to the ferroelectric layer. The first and second coercive fields Ec1 and Ec2 may be electric fields that are required to respectively switch the polarization orientation of the ferroelectric layer in opposite directions.

Referring to FIG. 1, the polarization state of the ferroelectric layer may be changed by applying an electric field E to the ferroelectric layer. As an example, an electric field E having a positive polarity may be applied to the ferroelectric layer having the second remanent polarization Pr2 in an initial state in which no electric field is applied. The electric field E may be applied to the ferroelectric layer while the magnitude is increased in a sweep method. When the electric field E reaches the first coercive field Ec1, the polarization state of the ferroelectric layer may be rapidly changed from the second remanent polarization Pr2 of the initial state to the first polarization P1 via a negative slope portion 10NC on the graph. When the electric field E is removed, the ferroelectric layer may have the first remanent polarization Pr1.

As another example, an electric field E having a negative polarity may be applied to the ferroelectric layer having the first remanent polarization Pr1 in an initial state in which no electric field is applied. The electric field E may be applied to the ferroelectric layer while the magnitude is increased in a sweeping manner. When the electric field E reaches the second coercive field Ec2, the polarization of the ferroelectric layer may be changed from the first remanent polarization Pr1 of the initial state to the second polarization P2 via a negative slope portion 10NC on the graph. When the electric field E is removed, the ferroelectric layer may have the second remanent polarization Pr2.

The capacitance of the ferroelectric layer may be proportional to the ratio ΔP/ΔE of a polarization change ΔP depending on an electric field change ΔE on the graph 10. Accordingly, in the electric field section corresponding to the negative slope portion 10NC of the graph 10, the ferroelectric layer may exhibit a negative capacitance in which the ratio ΔP/ΔE has a negative value. That is, when the ferroelectric layer performs polarization switching in the first and second coercive fields Ec1 and Ec2, the ferroelectric layer may pass through a portion of the graph 10, implementing a negative capacitance. Conversely, in the remaining portions, except for the negative slope portion 10NC in the graph 10 of FIG. 1, the ferroelectric layer may exhibit a positive capacitance in which the ratio ΔP/ΔE has a positive value.

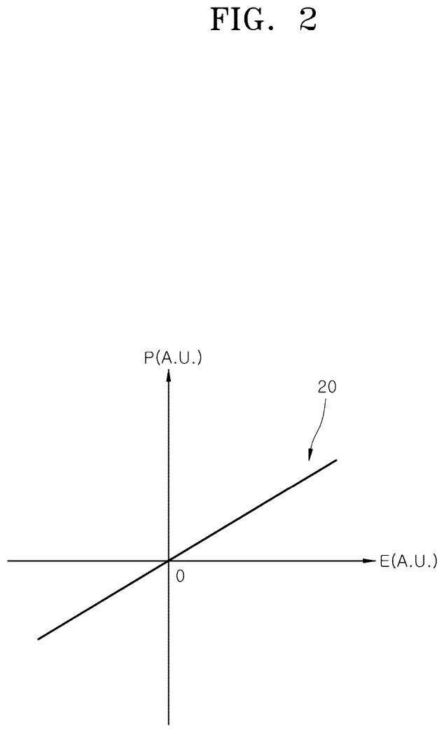

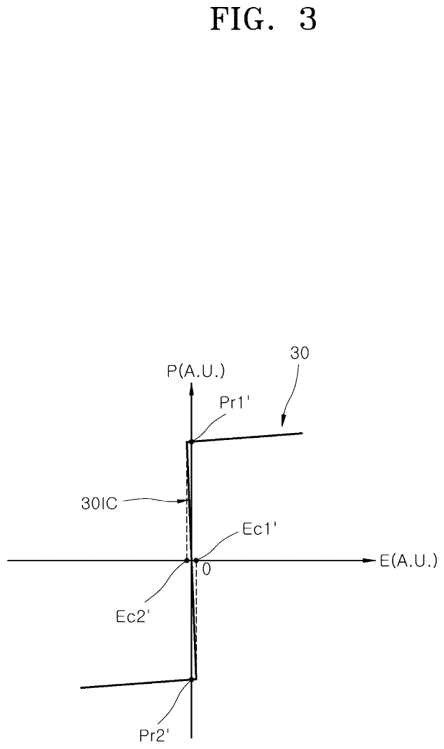

FIG. 2 is a graph schematically illustrating polarization characteristics of a dielectric layer included in a dielectric structure according to an embodiment of the present disclosure. FIG. 3 is a graph schematically illustrating polarization characteristics of a ferroelectric layer included in the dielectric structure according to an embodiment of the present disclosure.

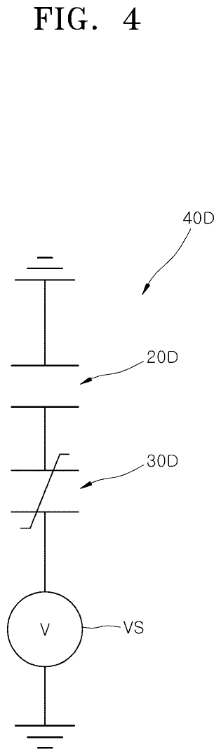

The graph 20 of FIG. 2 discloses a polarization behavior of the dielectric layer (e.g., a polarization behavior of a dielectric layer 20D included in a dielectric structure 40D of FIG. 4) depending on an electric field E. When applying the electric field E to both ends of the dielectric layer 20D while sweeping in a positive or negative direction, the polarization of the dielectric layer 20D may increase from zero (0) in proportion to the applied electric field E as shown in FIG. 2. When the electric field E is removed from the dielectric layer 20D, the magnitude of the polarization may return to zero (0). That is, when no electric field is applied to the dielectric layer 20D, the dielectric layer 20D might not have remanent polarization. The capacitance of the dielectric layer 20D may be proportional to the ratio ΔP/ΔE of a polarization change ΔP depending on an electric field change ΔE on the graph 20. Accordingly, the dielectric layer 20D may have a positive capacitance in the entire electric field section.

Referring to the graph 30 of FIG. 3, the ferroelectric layer included in the dielectric structure (e.g., a ferroelectric layer 30D included in the dielectric structure 40D of FIG. 4) according to an embodiment of the present disclosure may have a negative slope portion 30IC on the graph 30 in an electric field section between first and second coercive fields Ec1′ and Ec2′. The ferroelectric layer 30D of FIG. 4 may have first and second remanent polarization Pr1′ and Pr2′ after the electric field E applied to the ferroelectric layer 30D is removed, as shown in FIG. 3.

The first and second coercive fields Ec1′ and Ec2′ on the graph 30 of FIG. 3 may be much smaller than the first and second coercive fields Ec1 and Ec2 on the graph 10 of FIG. 1. That is, when the electric field E is applied from an initial state, polarization switching may occur immediately in the ferroelectric layer 30D. In addition, the polarization switching may abruptly increase the magnitude of the polarization of the ferroelectric layer 30D. Accordingly, the ratio ΔP/ΔE of a polarization change ΔP, depending on an electric field change ΔE of the ferroelectric layer 30D in the electric field section between the first and second coercive fields Ec1′ and Ec2′ on the graph 30, may be much greater than the ratio ΔP/ΔE of the polarization change of the ferroelectric layer on the graph 10. As an example, the ratio ΔP/ΔE of the polarization change of the ferroelectric layer 30D on the graph 30 may be 10 or greater. As another example, the ratio ΔP/ΔE of the polarization change of the ferroelectric layer 30D on the graph 30 may be 20 or greater. In another example, the ratio ΔP/ΔE of the polarization change of the ferroelectric layer 30D on the graph 30 may be 50 or greater.

As a result, when an electric field E is applied from the initial state, the ferroelectric layer 30D may have a very large capacitance value that is proportional to the ratio ΔP/ΔE of the polarization change ΔP. As an example, a case in which the ferroelectric layer 30D has a very large capacitance value may mean a case in which the ratio ΔP/ΔE of the polarization change ΔP, depending on the electric field change ΔE of the ferroelectric layer 30D, is 10 or greater.00

In an embodiment, the ferroelectric layer 30D may implement the polarization characteristics of the graph 30 more efficiently when the ferroelectric layer 30D are electrically connected with the dielectric layer having the polarization behavior of FIG. 2 (e.g., the dielectric layer 20D of FIG. 4). In an embodiment, as shown in FIG. 4, when the ferroelectric layer 30D and the dielectric layer 20D are connected in series to form the dielectric structure 40D, the ferroelectric layer 30D in the dielectric structure 40D may have the polarization characteristics of the graph 30. In an embodiment, the thickness of the ferroelectric layer 30D may be 5 nm or less, and the thickness of the ferroelectric layer 30D may be substantially the same as or less than the thickness of the dielectric layer 20D. In this case, when the thickness ratio of the ferroelectric layer 30D and the dielectric layer 20D is distributed within a predetermined range, the ferroelectric layer 30D may have ferroelectric polarization characteristics according to the graph 30 of FIG. 3 rather than the graph 10 of FIG. 1.

Although not necessarily explained by one theory, according to one of various theories, the polarization characteristics of the ferroelectric layer 30D in connection with the graph 30 of FIG. 3 may be described as follows. When the ferroelectric layer 30D having spontaneous polarization in a first direction is bonded to the dielectric layer 20D, a depolarization electric field that suppresses the spontaneous polarization may be generated in the ferroelectric layer 30D. The depolarization electric field may be formed from an interface between the ferroelectric layer 30D and the dielectric layer 20D in an inward direction of the ferroelectric layer 30D. In order to alleviate the depolarization electric field, first domains having a polarization orientation in the first direction and second domains having a polarization orientation in a second direction substantially opposite to the first direction may be formed alternately in the ferroelectric layer 30D. In an embodiment, the first and second directions are directions that are substantially perpendicular to the interface between the ferroelectric layer 30D and the dielectric layer 20D.

In other words, the ferroelectric layer 30D may have a stripe-type domain structure including the plurality of first domains and the plurality of second domains. In this case, as described above, when the thickness ratio of the ferroelectric layer 30D and the dielectric layer 20D is controlled within a predetermined range and the size of the first domain and the size of the second domain are reduced to a size of two unit cells or less or a size of three unit cells or less of the ferroelectric layer 30D, the ferroelectric layer 30D may exhibit the ferroelectric characteristics as illustrated in FIG. 3. As an example, one unit cell of the ferroelectric layer 30D may have a size of about 5 Å.

Meanwhile, as described above, when the ferroelectric layer 30D has the polarization characteristics of FIG. 3 when bonded with the dielectric layer 20D, the dielectric structure including the bonded ferroelectric layer 30D and the dielectric layer 20D might not exhibit ferroelectricity as a whole. This may be because the depolarization electric field that is generated by the bonding of the ferroelectric layer 30D and the dielectric layer 20D functions to offset the spontaneous polarization inside the ferroelectric layer 30D. As a result, the dielectric structure as a whole may exhibit non-ferroelectricity, such as paraelectricity. The non-ferroelectricity of the dielectric structure may be described in more detail with reference to an electric circuit in FIG. 4.

FIG. 4 is a circuit diagram schematically illustrating an electric circuit configuration of a dielectric structure according to an embodiment of the present disclosure. Referring to the circuit diagram of FIG. 4, the dielectric structure 40D may include a dielectric layer 20D and a ferroelectric layer 30D that are electrically connected in series to each other.

The dielectric layer 20D and the ferroelectric layer 30D may have the polarization characteristics that are described above with reference to FIGS. 2 and 3, respectively. The dielectric structure 40D may exhibit non-ferroelectricity as a whole.

Meanwhile, when a voltage is applied to both ends of the dielectric structure 40D through a power supply VS, the capacitance C_{T} of the dielectric structure 40D may be calculated by Equation (1) below.

$$1 / ( {C}_{T} ) = 1 / ( {C}_{D E} ) + 1 / ( {C}_{F E} ) \qquad ( 1 )$$

Here, C_{DE} may be the capacitance of the dielectric layer 20D, and C_{FE} may be the capacitance of the ferroelectric layer 30D.

When the ferroelectric layer 30D has a very large capacitance, 1/(C_{FE}) may be calculated to be a very small value and may be neglected in the calculation of Equation (1). Accordingly, the capacitance C_{T} of the dielectric structure 40D may be substantially the same as the capacitance C_{DE} of the dielectric layer 20D.

As a result, the dielectric layer 20D may substantially function as a capacitor dielectric layer of the dielectric structure 40D. The ferroelectric layer 30D may function to prevent or alleviate the deterioration of the leakage current and breakdown voltage characteristics of the dielectric structure 40D, as a barrier dielectric layer having a predetermined thickness.

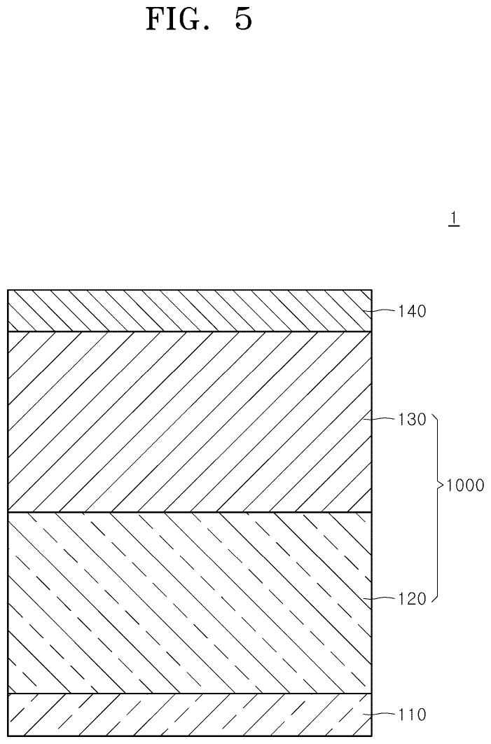

FIG. 5 is a cross-sectional view schematically illustrating a semiconductor device 1 according to an embodiment of the present disclosure. Referring to FIG. 5, the semiconductor device 1 may be a capacitor device including a first electrode 110 and a second electrode 140 that are disposed to be spaced apart from each other, and a dielectric structure 1000 disposed between the first electrode 110 and the second electrode 140. The dielectric structure 1000 may include a ferroelectric layer 120 and a dielectric layer 130.

The dielectric structure 1000 may have non-ferroelectricity. In this specification, non-ferroelectricity may mean that a dielectric material has no remanent polarization and no coercive field. As an example, non-ferroelectricity may mean paraelectricity. As described above with reference to FIG. 4, the capacitance of the dielectric structure 1000 may be substantially the same as the capacitance of the dielectric layer 130. That is, the capacitance of the dielectric structure 1000 may be determined by the capacitance of the dielectric layer 130.

The first electrode 110 may include a conductive material. The conductive material may include, for example, doped silicon (Si), gold (Au), silver (Ag), tungsten (W), titanium (Ti), copper (Cu), aluminum (Al), ruthenium (Ru), platinum (Pt), iridium (Ir), iridium oxide, tungsten nitride, titanium nitride, tantalum nitride, tungsten carbide, titanium carbide, tungsten silicide, titanium silicide, tantalum silicide, ruthenium oxide, or a combination of two or more thereof.

Referring to FIG. 5, the ferroelectric layer 120 may be disposed on the first electrode 110. The ferroelectric layer 120 may have ferroelectricity that is substantially the same as that of the ferroelectric layer 30D, described above with reference to FIG. 3. The ferroelectric layer 120 may function as a barrier dielectric layer of the dielectric structure 1000, such as the ferroelectric layer 30D of the dielectric structure 40D described with reference to FIG. 4.

The ferroelectric layer 120 may include a ferroelectric material. In an embodiment, the ferroelectric layer 120 may include hafnium zirconium oxide. In another embodiment, the ferroelectric layer 120 may include a dopant that is doped in the hafnium zirconium oxide. The dopant may stabilize the ferroelectricity of the ferroelectric layer 120. The dopant may include, for example, carbon (C), silicon (Si), magnesium (Mg), aluminum (Al), yttrium (Y), nitrogen (N), germanium (Ge), tin (Sn), strontium (Sr), lead (Pb), calcium (Ca), barium (Ba), titanium (Ti), zirconium (Zr), gadolinium (Gd), lanthanum (La), or a combination of two or more thereof.

In an embodiment, the ferroelectric layer 120 may have a crystal structure of an orthorhombic crystal system. For example, the ferroelectric layer 120 may have a thickness of 1 nm to 5 nm. The ferroelectric layer 120 may have a single crystalline or polycrystalline structure. In an embodiment, the ferroelectric layer 120 may be an epi-growth layer. The ferroelectric layer 120 may be epitaxially formed on the first electrode 110 through, for example, atomic layer deposition, pulsed layer deposition, or chemical vapor deposition.

Referring to FIG. 5, the dielectric layer 130 may be disposed on the ferroelectric layer 120. The dielectric layer 130 may have a non-ferroelectricity that is substantially the same as that of the dielectric layer 20D, described above with reference to FIG. 2. The dielectric layer 130 may have paraelectricity, for example. The dielectric layer 130 may function as a capacitor dielectric layer of the dielectric structure 1000, such as the dielectric layer 20D of the dielectric structure 40D described with reference to FIG. 4. The dielectric layer 130 may have a thickness of 1 nm to 5 nm, for example.

In an embodiment, the dielectric layer 130 may be an epi-growth layer. The dielectric layer 130 may be epitaxially formed on the ferroelectric layer 120 through, for example, atomic layer deposition, pulsed layer deposition, or chemical vapor deposition.

The dielectric layer 130 may include a non-ferroelectric material. As an example, the non-ferroelectric material may be a paraelectric material. In an embodiment, the dielectric layer 130 may include hafnium oxide, zirconium oxide, or a combination thereof. The dielectric layer 130 may have a crystal structure of a monoclinic crystal system or a tetragonal crystal system.

Referring to FIG. 5 again, the second electrode 140 may be disposed on the dielectric layer 130. The second electrode 140 may include a conductive material. The conductive material may include, for example, doped silicon (Si), gold (Au), silver (Ag), tungsten (W), titanium (Ti), copper (Cu), aluminum (Al), ruthenium (Ru), platinum (Pt), iridium (Ir), iridium oxide, tungsten nitride, titanium nitride, tantalum nitride, tungsten carbide, titanium carbide, tungsten silicide, titanium silicide, tantalum silicide, ruthenium oxide, or a combination of two or more thereof.

The ferroelectric layer 120 and the dielectric layer 130 of the dielectric structure 1000 may be connected in series to each other between the first electrode 110 and the second electrode 140. Accordingly, the dielectric structure 1000 may have a configuration that is substantially the same as the configuration of the dielectric structure 40D of FIG. 4. That is, the dielectric structure 1000 may include the dielectric layer 130 as a capacitor dielectric layer and may include the ferroelectric layer 120 as a barrier dielectric layer. Despite the ferroelectric layer 120 and the dielectric layer 130 being connected in series, the dielectric structure 1000 may have a capacitance that is substantially the same as the capacitance of the dielectric layer 130. In addition, the dielectric structure 1000 may improve the leakage current and breakdown voltage characteristics due to the electrical barrier function that is performed by the ferroelectric layer 120.

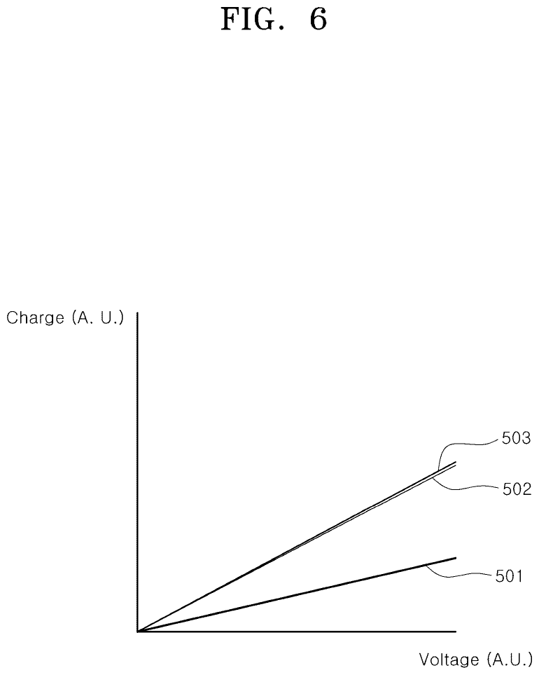

FIG. 6 illustrates graphs schematically illustrating the results of simulating the charge amounts of semiconductor devices depending on applied voltages. First to third graphs 501, 502, and 503 of FIG. 6 may be graphs of the charging characteristics of first to third semiconductor devices including first to third dielectric structures, respectively. In the first to third graphs 501, 502, and 503, the charge amount changes ΔQ depending on the voltage changes ΔV, that is, the slopes of the first to third graphs 501, 502, and 503 may correspond to the capacitances of the first to third dielectric structures, respectively.

The first and second graphs 501 and 502 may represent charging characteristics of the first and second semiconductor devices, which are comparative examples of the present disclosure, and the third graph 503 may represent charging characteristics of the third semiconductor device, which is an embodiment of the present disclosure.

The first dielectric structure may be a paraelectric structure in which a zirconium oxide layer, an aluminum oxide layer, and a zirconium oxide layer are sequentially stacked, and may have a first thickness. Each of the zirconium oxide layer and the aluminum oxide layer may have paraelectricity. The second dielectric structure may have the same configuration as the first dielectric structure, but may have a second thickness corresponding to 40% of the first thickness. The third dielectric structure may be a paraelectric structure in which a hafnium zirconium oxide layer, which is a ferroelectric layer, and a zirconium oxide layer, which is a dielectric layer, are stacked, and may have the first thickness.

Referring to FIG. 6, the charge amount change ΔQ, depending on the voltage change ΔV of the first graph 501, may be the smallest. In addition, the charge amount change ΔQ, depending on the voltage change ΔV of each of the second graph 502 and the third graph 503, may be substantially the same. Accordingly, although the third dielectric structure of the third graph 501 has a thickness that is 2.5 times greater than that of the second dielectric structure of the second graph 502, the third dielectric structure may have substantially the same capacitance as the second dielectric structure.

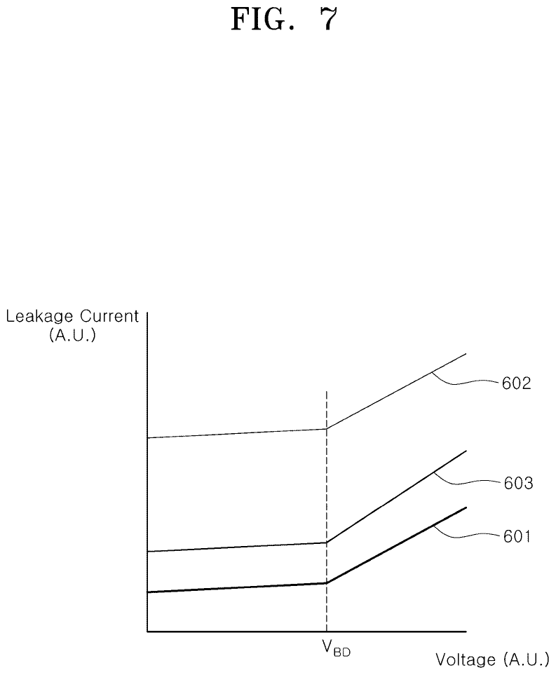

FIG. 7 illustrates graphs schematically illustrating results of simulating leakage currents of semiconductor devices depending on applied voltages. First to third graphs 601, 602, and 603 of FIG. 7 may be graphs that are obtained by calculating the leakage currents that are generated from the first to third dielectric structures when a voltage is applied to the first to third dielectric structures, described in relation to FIG. 6.

Referring to FIG. 7, the leakage current of the first dielectric structure of the first graph 601 may represent the lowest value. The first dielectric structure may include a zirconium oxide layer, an aluminum oxide layer, and a zirconium oxide layer, each of which is a paraelectric layer. The first dielectric structure may have the first thickness. In addition, the leakage current of the second dielectric structure of the second graph 602 may represent the highest value. The second dielectric structure may have a thickness corresponding to 40% of the thickness of the first dielectric structure. Meanwhile, the third dielectric structure of the third graph 603 may have a leakage current value between the leakage current values of the first dielectric structure and the second dielectric structure.

Referring to FIGS. 6 and 7 together, the third dielectric structure may have substantially the same capacitance as the second dielectric structure and may have superior leakage current characteristics than the second dielectric structure. Meanwhile, in the first to third graphs 601, 602, and 603, when the applied voltage is equal to or greater than a breakdown voltage V_{BD}, a weak level of breakdown may occur, and the leakage current may be increased.

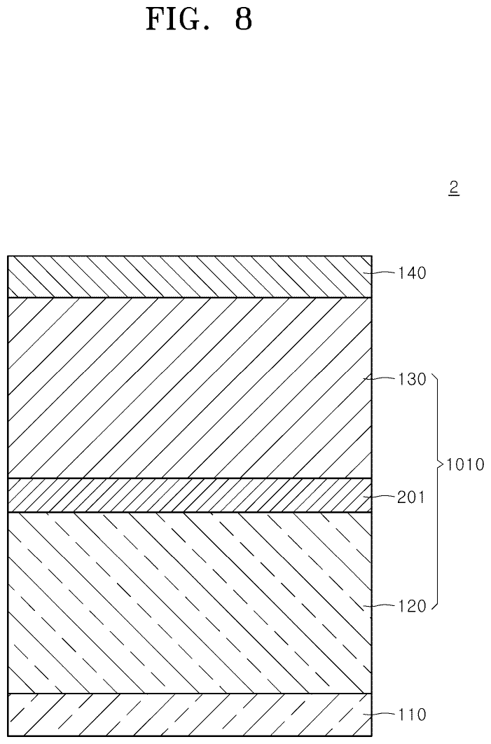

FIGS. 8 to 13 are cross-sectional views schematically illustrating semiconductor devices according to various embodiments of the present disclosure. In FIGS. 8 to 13, the same reference numerals denote the same components. FIG. 8 is a cross-sectional view schematically illustrating a semiconductor device 2 according to another embodiment of the present disclosure. In the semiconductor device 2 of FIG. 8, besides the components of the semiconductor device 1 of FIG. 5, a dielectric structure 1010 may further include an interfacial insulation layer 201.

The interfacial insulation layer 201 may be disposed between a ferroelectric layer 120 and a dielectric layer 130. The interfacial insulation layer 201 may suppress or reduce material exchanges between the ferroelectric layer 120 and the dielectric layer 130. Accordingly, it is possible to prevent or alleviate the changes of the material composition of the ferroelectric layer 120 and the dielectric layer 130. Therefore, the ferroelectricity of the ferroelectric layer 120, associated with FIG. 3, may be stabilized, and the non-ferroelectricity of the dielectric layer 130, associated with FIG. 2, may be stabilized. As a result, it is possible to reliably secure the capacitance of the dielectric structure 1010 through the series connection of the ferroelectric layer 120 and the dielectric layer 130.

In addition, the interfacial insulation layer 201 may have a band gap energy that is greater than the band gap energy of each of the ferroelectric layer 120 and the dielectric layer 130. Accordingly, the interfacial insulation layer 201 may form a potential barrier between the ferroelectric layer 120 and the dielectric layer 130. As a result, the interfacial insulation layer 201 may reduce the leakage current that is generated at the interface between the ferroelectric layer 120 and the dielectric layer 130, and the interfacial insulation layer 201 may increase the breakdown voltage of the dielectric structure 1010 during the operation of the semiconductor device 2.

In an embodiment, the interfacial insulation layer 201 may have an amorphous crystal structure. The thickness of the interfacial insulation layer 201 may be sufficiently thin so that the crystal structure of the dielectric layer 130 in contact with the interfacial insulation layer 201 is influenced by the crystal structure of the ferroelectric layer 120. Therefore, the dielectric layer 130 may grow into an epitaxial structure on the interfacial insulation layer 201. That is, the dielectric layer 130 may have a crystal structure similar to that of the ferroelectric layer 120 despite the interfacial insulation layer 201 being inserted therebetween. However, the crystal structure of the dielectric layer 130 may be different from the crystal structure of the ferroelectric layer 120. As an example, the ferroelectric layer 120 may have a crystal structure of an orthorhombic crystal system, while the dielectric layer 130 may have a crystal structure of a monoclinic crystal system or a tetragonal crystal system. The interfacial insulation layer 201 may include, for example, aluminum oxide, yttrium oxide, magnesium oxide, or a combination of two or more thereof.

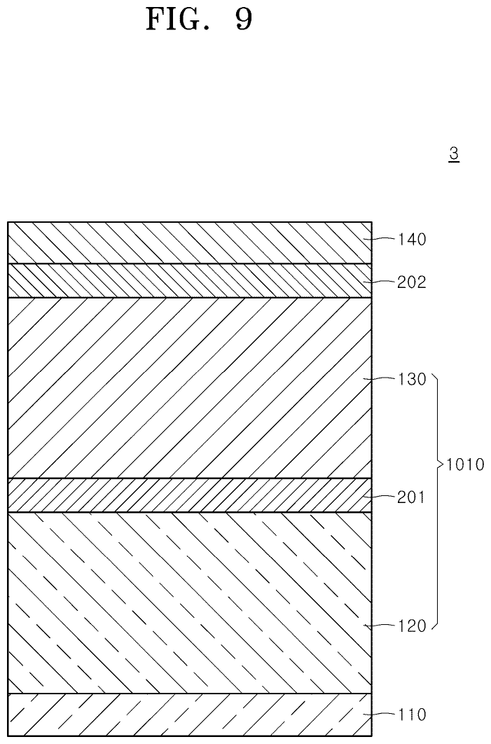

FIG. 9 is a cross-sectional view schematically illustrating a semiconductor device 3 according to another embodiment of the present disclosure. Besides the components of the semiconductor device 2 of FIG. 8, the semiconductor device 3 of FIG. 9 may further include an interfacial insulation layer 202 that is disposed between the dielectric layer 130 and the second electrode 140. Hereinafter, the interfacial insulation layer 201 in the dielectric structure 1010 will be referred to as the first interfacial insulation layer 201, and the interfacial insulation layer 202 that is disposed between the dielectric layer 130 and the second electrode 140 will be referred to as the second interfacial insulation layer 202.

The second interfacial insulation layer 202 may suppress or reduce material exchanges between the dielectric layer 130 and the second electrode 140. Accordingly, the change of the material composition of the dielectric layer 130 may be prevented or alleviated.

In addition, the band gap energy of the second interfacial insulation layer 202 may be greater than the band gap energy of the dielectric layer 130. Accordingly, the second interfacial layer 202 may form a potential barrier between the dielectric layer 130 and the second electrode 140. The second interfacial insulation layer 202 may reduce a leakage current that is generated at the interface between the dielectric layer 130 and the second electrode 140 during the operation of the semiconductor device 3. As a result, the breakdown voltage of the semiconductor device 3 may be increased.

In an embodiment, the second interfacial insulation layer 202 may include, for example, aluminum oxide, yttrium oxide, magnesium oxide, or a combination of two or more thereof. The second interfacial insulation layer 202 may have an amorphous crystal structure.

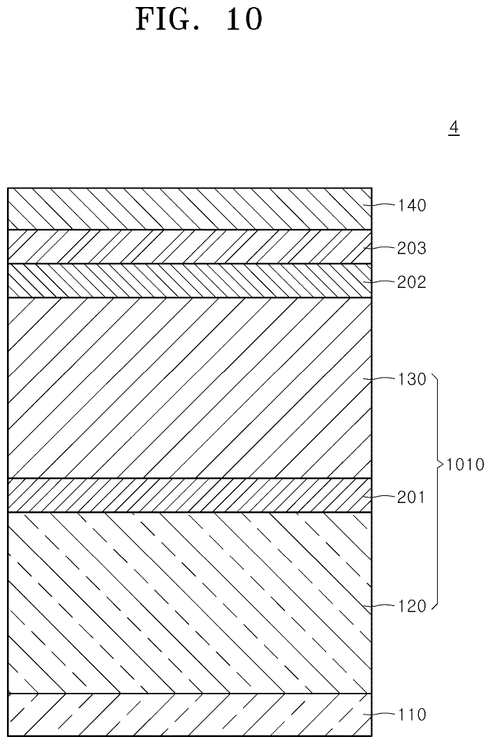

FIG. 10 is a cross-sectional view schematically illustrating a semiconductor device 4 according to further another embodiment of the present disclosure. Besides the components of the semiconductor device 3 of FIG. 9, the semiconductor device 4 of FIG. 10 may further include a reduction sacrificial layer 203.

The reduction sacrificial layer 203 may be disposed between the second interfacial insulation layer 202 and the second electrode 140. The reduction sacrificial layer 203 may serve to suppress or alleviate the second interfacial insulation layer 202 and the second electrode 140 from reacting with each other. That is, the reduction sacrificial layer 203 may react with the second electrode 140 in advance to form a compound layer, thereby preventing or alleviating the second interfacial insulation layer 202 from being reduced through a reaction with the second electrode 140. Accordingly, the material composition of the second interfacial insulation layer 202 may be stably maintained. The reduction sacrificial layer 203 may include, for example, niobium oxide or titanium oxide.

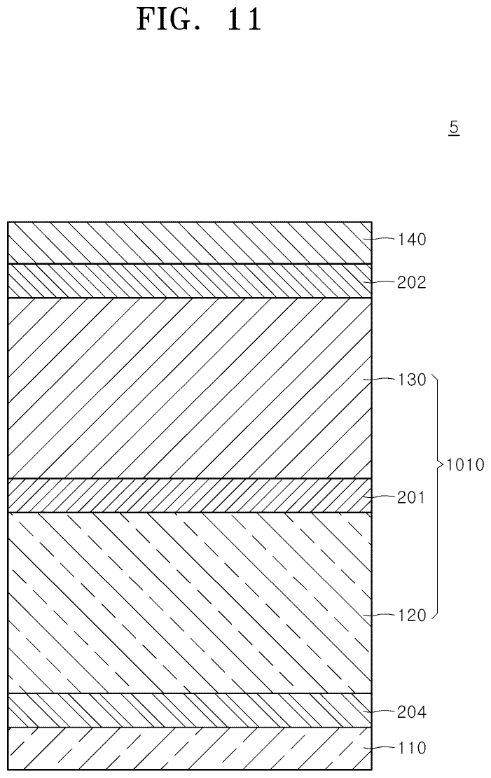

FIG. 11 is a cross-sectional view schematically illustrating a semiconductor device 5 according to further another embodiment of the present disclosure. Besides the components of the semiconductor device 3 of FIG. 9, the semiconductor device 5 of FIG. 11 may further include a third interfacial insulation layer 204.

The third interfacial insulation layer 204 may be disposed between the first electrode 110 and the ferroelectric layer 120. The third interfacial insulation layer 204 may suppress or reduce material exchanges between the first electrode 110 and the ferroelectric layer 120. Accordingly, it is possible to prevent or alleviate the change of the material composition of the ferroelectric layer 120.

In addition, the band gap energy of the third interfacial insulation layer 204 may be greater than the band gap energy of the ferroelectric layer 120. Accordingly, the third interfacial insulation layer 204 may form a potential barrier between the first electrode 110 and the ferroelectric layer 120. The third interfacial insulation layer 204 may reduce a leakage current that is generated at the interface between the first electrode 110 and the ferroelectric layer 120 during the operation of the semiconductor device 5. As a result, the breakdown voltage of the semiconductor device 5 may be increased.

In an embodiment, the third interfacial insulation layer 204 may include, for example, aluminum oxide, yttrium oxide, magnesium oxide, or a combination of two or more thereof.

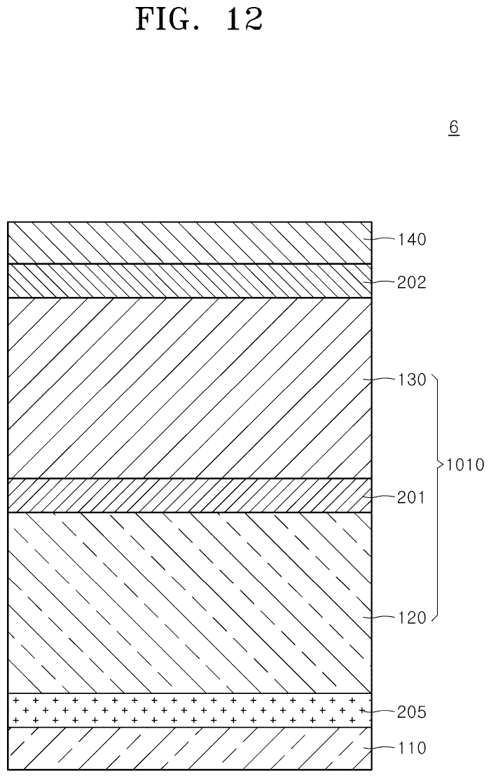

FIG. 12 is a cross-sectional view schematically illustrating a semiconductor device 6 according to yet another embodiment of the present disclosure. Besides the components of the semiconductor device of FIG. 9, the semiconductor device 6 of FIG. 12 may further include a crystallization seed layer 205.

The crystallization seed layer 205 may be disposed between the first electrode 110 and the ferroelectric layer 120. The crystallization seed layer 205 may have a crystalline crystal structure and may induce the crystallization of the ferroelectric layer 120. In an embodiment, the ferroelectric layer 120 may be formed in an amorphous material layer on the crystallization seed layer 205 and then may be converted to have a crystalline crystal structure through a crystallization heat treatment by using the crystallization seed layer 205. The conversion into the crystalline structure of the ferroelectric layer 120 may improve the ferroelectricity of the ferroelectric layer 120. The crystallization seed layer 205 may have a non-ferroelectric property.

Furthermore, the crystallization seed layer 205 may function as a buffer layer capable of reducing a difference in lattice constant between the first electrode 110 and the ferroelectric layer 120. As an example, the crystallization seed layer 205 may have a lattice constant between the lattice constant of the first electrode 110 and the lattice constant of the ferroelectric layer 120. The crystallization seed layer 205 may suppress or reduce defects that may occur at the interface where the first electrode 110 and the ferroelectric layer 120 directly contact each other. Accordingly, the crystallization seed layer 205 may reduce the leakage current that may occur at the interface between the first electrode 110 and the ferroelectric layer 120. The crystallization seed layer 205 may include, for example, magnesium oxide or zirconium oxide.

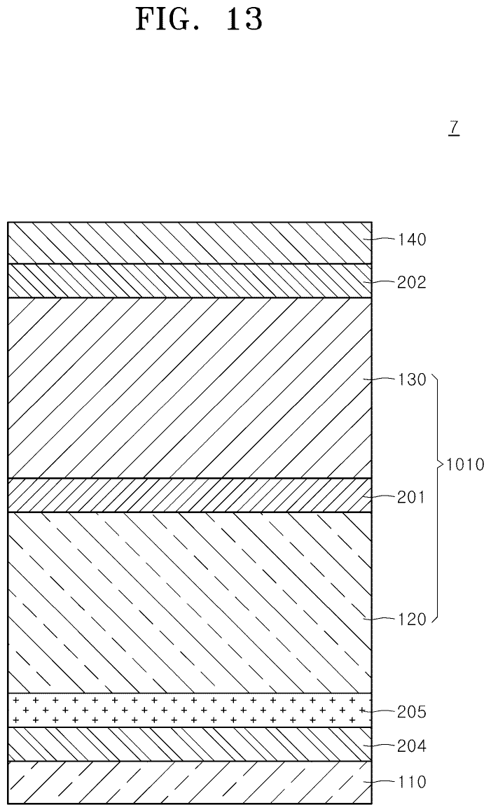

FIG. 13 is a cross-sectional view schematically illustrating a semiconductor device 7 according to still yet another embodiment of the present disclosure. Referring to FIG. 13, besides the components of the semiconductor device 6 of FIG. 10, the semiconductor device 7 may further include a third interfacial insulation layer 204 that is disposed between the first electrode 110 and the crystallization seed layer 205. Accordingly, the semiconductor device 7 may perform the function of the third interfacial insulation layer 204 of the semiconductor device 5, described with reference to FIG. 11, and the function of the crystallization seed layer 205 of the semiconductor device 6, described with reference to FIG. 12, together. The configuration of the semiconductor device 7 may be substantially the same as that of the semiconductor device 6 of FIG. 10, except for the third interfacial insulation layer 204. Accordingly, overlapping descriptions have been omitted.

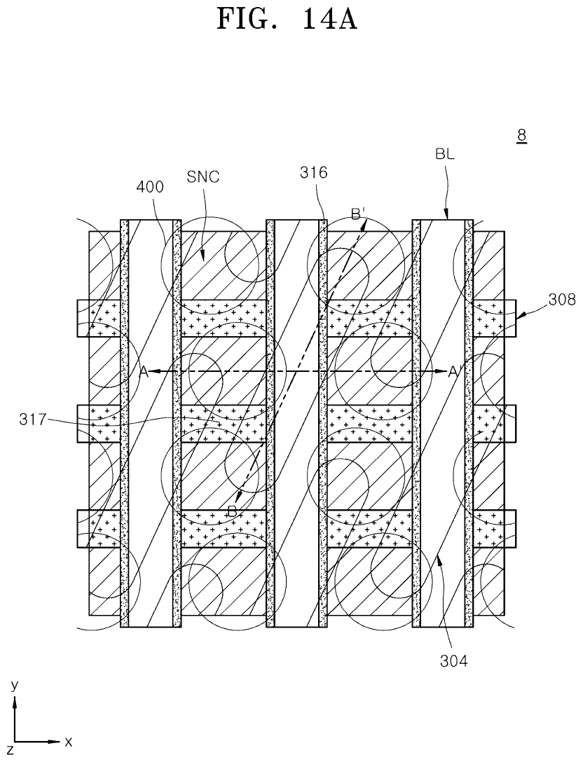

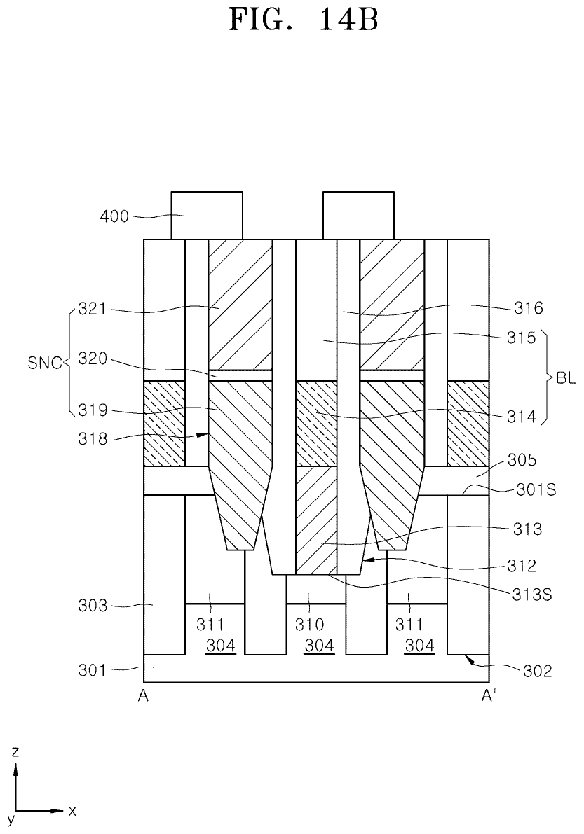

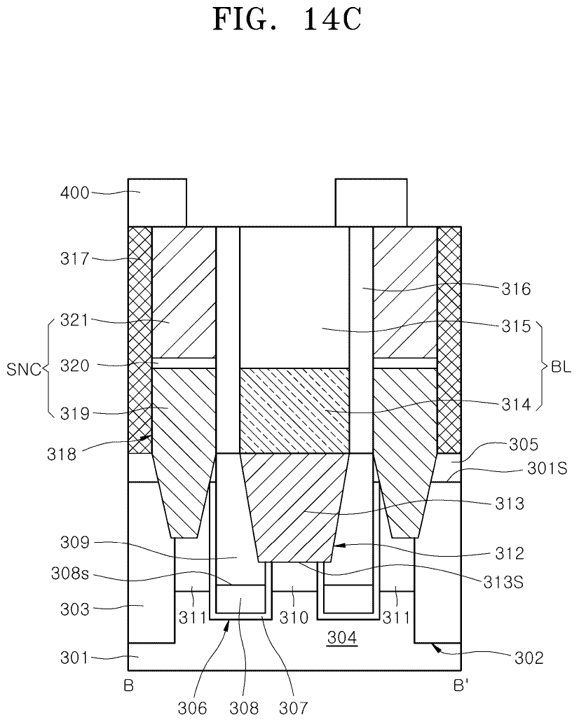

FIG. 14A is a plan view schematically illustrating memory cells of an electronic device according to an embodiment of the present disclosure. FIG. 14B is a cross-sectional view of the memory cells of FIG. 14A taken along line A-A′. FIG. 14C is a cross-sectional view of the memory cells of FIG. 14A taken along line B-B′.

Referring to FIGS. 14A to 14C, each of the memory cells 8 may include a cell transistor including a buried word line 308 that is disposed in a substrate 301, a bit line 314, and a cell capacitor 400.

The substrate 301 may include a semiconductor material. The substrate 301 may include device isolation layers 303 and active regions 304. The active region 304 may be doped with an n-type or p-type dopant. Among the active regions 304, cell regions may be doped with a p-type dopant. The active regions 304 may be defined as regions of the substrate 301 that are separated by the device isolation layers 303. The device isolation layers 303 may be formed through a shallow trench isolation (STI) process and may be disposed in device isolation trenches 302 that are formed in the substrate 301.

Referring to FIG. 14C, word line trenches 306 may be formed in the substrate 301. A gate insulation layer 307 may be disposed on an inner surface of each of the word line trenches 306. The buried word line 308 may be disposed on the gate insulation layer 307 in each of the word line trenches 306. The buried word line 308 may partially fill each of the word line trenches 306.

A word line capping layer 309 may be disposed on the buried word line 308 in each of the word line trenches 306. An upper surface 308S of the buried word line 308 may be located at a lower level than a surface 301S of the substrate 301. The buried word line 308 may include a conductive material. In an embodiment, the buried word line 308 may be a thin film structure including a titanium nitride (TiN) layer and a tungsten (W) layer. In another embodiment, the buried word line 308 may include a single layer of titanium nitride (TiN) or a single layer of tungsten (W).

Referring to FIGS. 14B and 14C, first and second doping regions 310 and 311 may be disposed in the active regions 304 of the substrate 301. The first and second doping regions 310 and 311 may be spaced apart from each other by the word line trenches 306. One of the first and second doping regions 310 and 311 may be a source region of the cell transistor, and the other may be a drain region of the cell transistor. Each of the first and second doping regions 310 and 311 may include an n-type dopant, such as arsenide (As) or phosphorus (P).

As described above, the buried word line 308 and the first and second doping regions 310 and 311 may constitute the cell transistor. The buried word lines 308 may extend in the x-direction of FIG. 14A.

Referring to FIGS. 14B and 14C, a bit line contact plug 313 may be disposed on the substrate 301. The bit line contact plug 313 may be electrically connected to the first doping region 310. The bit line contact plug 313 may be disposed in a bit line contact hole 312. The bit line contact hole 312 may be formed in the substrate 301 and a hard mask layer 305 that are disposed on the substrate 301. A lower surface 313S of the bit line contact plug 313 may be located at a lower level than the upper surface 301S of the substrate 301. The bit line contact plug 313 may include a conductive material. A bit line structure BL may be disposed on the bit line contact plug 313. The bit line structure BL may include a bit line 314 in contact with the bit line contact plug 313 and a bit line hard mask 315 that is disposed on the bit line 314.

Referring to FIGS. 14A to 14C together, the bit lines 314 may extend in a direction (e.g., the y-direction) that crosses the buried word lines 308. The bit lines 314 may be electrically connected to the first doping regions 310 through the bit line contact plugs 313. Each of the bit lines 314 may include a conductive material. Each of the bit line hard masks 315 may include an insulation material.

A bit line spacer 316 may be disposed on sidewalls of each of the bit line structures BL. The bit line spacer 316 may extend to cover both sidewalls of each of the bit line contact plugs 313. The bit line spacer 316 may include silicon oxide, silicon nitride, or a combination thereof. In another embodiment, the bit line spacer 316 may include an air gap. As an example, the bit line spacer 316 may have a nitride-air gap-nitride (NAN) structure in which an air gap is located between silicon nitride layers.

Storage node contact plugs (SNCs) may be disposed between the bit line structures BL. Each of the storage node contact plugs (SNCs) may be disposed in a storage node contact hole 318. The storage node contact plugs (SNCs) may be electrically connected to the second doping regions 311. In an embodiment, each of the storage node contact plugs (SNCs) may include a lower plug 319 and an upper plug 321. Each of the storage node contact plugs (SNCs) may further include an ohmic contact layer 320 between the lower plug 319 and the upper plug 321. In an embodiment, the upper plug 321 may include metal, the lower plug 319 may include doped silicon, and the ohmic contact layer 320 may include metal silicide.

Referring to FIG. 14C, a plug isolation layer 317 may be disposed on the hard mask layer 305. The plug isolation layer 317 may be an insulation layer that is disposed between neighboring bit line structures BL. The storage node contact holes 318 may penetrate the plug isolation layer 317 and the hard mask layer 305 to be formed over the active regions 304.

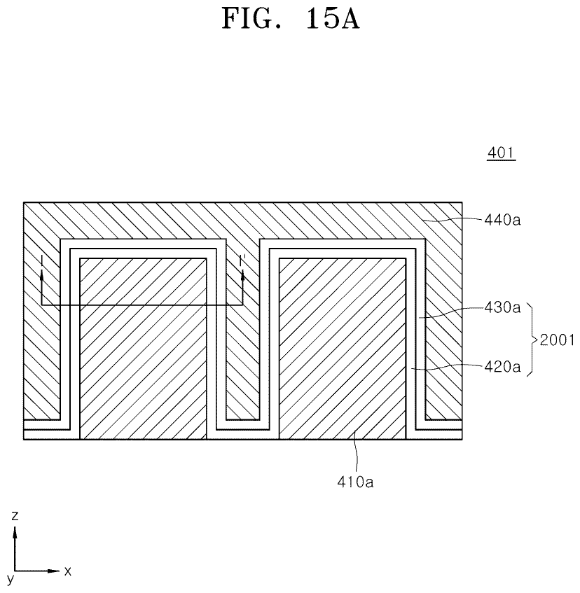

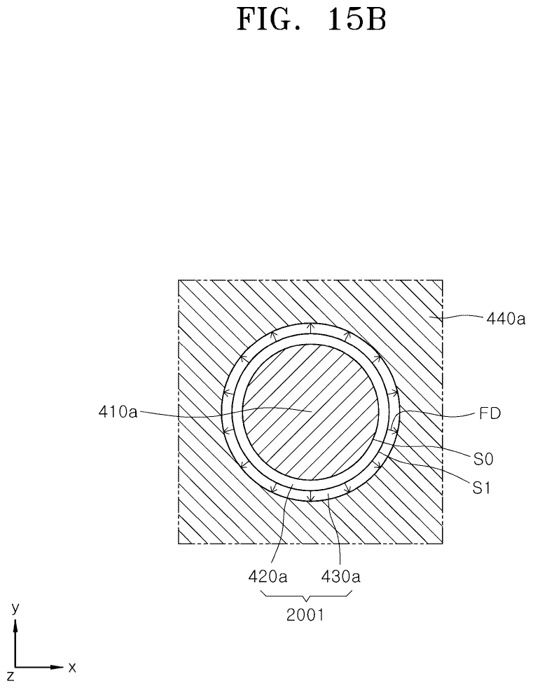

Referring to FIGS. 14A to 14C, each cell capacitor 400 may be disposed on the storage node contact plug (SNC). Each of the cell capacitors 400 may have a configuration of one of the semiconductor device 1 of FIG. 5, the semiconductor device 2 of FIG. 8, the semiconductor device 3 of FIG. 9, the semiconductor device 4 of FIG. 10, the semiconductor device 5 of FIG. 11, the semiconductor device 6 of FIG. 12, and the semiconductor device 7 of FIG. 13. The configuration of the cell capacitor 400 will be described in more detail with reference to the embodiments of FIGS. 15A and 15B, FIG. 16, FIGS. 17A and 17B, FIGS. 18A and 18B, FIG. 19, FIGS. 20A and 20B, FIG. 21, and FIGS. 22A and 22B below. In the descriptions with reference to the embodiments below, the expression of a singular form of a word herein may include the plural forms of the word unless clearly used otherwise in the context.

FIG. 15A is a cross-sectional view schematically illustrating a semiconductor device 401 according to an embodiment of the present disclosure. FIG. 15B is a cross-sectional view of the semiconductor device 401 of FIG. 15A taken along line I-I′ and shown on the x-y plane. In an embodiment, the semiconductor device 401 may include a capacitor. As an example, the semiconductor device 401 may be applied to the cell capacitor 400 of the memory cell 8 of FIGS. 14A to 14C.

Referring to FIG. 15A, the semiconductor device 401 may have a three-dimensional structure. The semiconductor device 401 may include a pillar-shaped storage node electrode 410a, a dielectric structure 2001 that is disposed on the storage node electrode 410a, and a plate electrode 440a that is disposed on the dielectric structure 2001. The dielectric structure 2001 may include a capacitor dielectric layer 420a and a barrier dielectric layer 430a that are connected in series to each other. The capacitor dielectric layer 420a may include a non-ferroelectric material, and the barrier dielectric layer 430a may include a ferroelectric material. In the semiconductor device 401, the storage node electrode 410a may be an electrode to which an operating voltage is applied, and the plate electrode 440a may be a ground electrode.

In an embodiment, the storage node electrode 410a may be disposed on the storage node contact plug (SNC) of the memory cell 8, described above with reference to FIGS. 14A to 14C. The storage node electrode 410a may be electrically connected to a second doping region 311 of a substrate 301 through the storage node contact plug (SNC).

Referring to FIGS. 15A and 15B, the storage node electrode 410a may include a pillar-shaped conductive structure. The capacitor dielectric layer 420a may be disposed to cover the storage node electrode 410a. The barrier dielectric layer 430a may be disposed to cover the capacitor dielectric layer 420a. The plate electrode 440a may be disposed to cover the barrier dielectric layer 430a.

In an embodiment, the semiconductor device 401 may correspond to the semiconductor device 1, described with reference to FIG. 5. As an example, the storage node electrode 410a, the dielectric structure 2001, and the plate electrode 440a of the semiconductor device 401 may correspond to the second electrode 140, the dielectric structure 1000, and the first electrode 110 of the semiconductor device 1, respectively.

As described above with reference to FIGS. 1 to 4, the thickness ratio between the barrier dielectric layer 430a and the capacitor dielectric layer 420a may be controlled within a predetermined range. Accordingly, the barrier dielectric layer 430a may exhibit the ferroelectric characteristics as illustrated in FIG. 3. In addition, the dielectric structure 2001 including the barrier dielectric layer 430a and the capacitor dielectric layer 420a, connected in series to each other, with the thickness ratio within the predetermined range, may have non-ferroelectricity, described above with reference to FIG. 4. That is, the capacitance of the dielectric structure 2001 may be substantially the same as the capacitance of the capacitor dielectric layer 420a. Each of the capacitor dielectric layer 420a and the barrier dielectric layer 430a may have, for example, a thickness of 1 nm to 5 nm.

As for the storage node electrode 410a, the pillar-shaped conductive structure may directly function as an electrode. That is, the dielectric structure 2001 may be directly disposed on the pillar-shaped conductive structure. The conductive structure may include, for example, doped silicon (Si), gold (Au), silver (Ag), tungsten (W), titanium (Ti), copper (Cu), aluminum (Al), ruthenium (Ru), platinum (Pt), iridium (Ir), iridium oxide, tungsten nitride, titanium nitride, tantalum nitride, tungsten carbide, titanium carbide, tungsten silicide, titanium silicide, tantalum silicide, ruthenium oxide, or a combination of two or more thereof.

Referring to FIGS. 15A and 15B, in the semiconductor device 401 of a three-dimensional structure, the capacitor dielectric layer 420a may be disposed closer to the storage node electrode 410a than the barrier dielectric layer 430a. According to an embodiment of the present disclosure, when a voltage is applied between the storage node electrode 410a and the plate electrode 440a, in a case in which the barrier dielectric layer 430a is disposed to surround the capacitor dielectric layer 420a with respect to the storage node electrode 410a, a depolarization electric field that is formed toward the barrier dielectric layer 430a, that is, in an inner direction of the barrier dielectric layer 430a, as shown in FIG. 15B, at the interface S1 between the capacitor dielectric layer 420a and the barrier dielectric layer 430a, may be relatively increased compared to a case in which the capacitor dielectric layer 420a is disposed to surround the barrier dielectric layer 430a.

That is, in FIG. 15B, for example, when a positive bias is applied to the storage node electrode 410a in a state in which the plate electrode 440a is grounded, ferroelectric polarization FD may be formed inside the barrier dielectric layer 430a in a direction substantially perpendicular to an outer circumferential surface S0 of the storage node electrode 410a. In this case, the negative charges that are generated by the ferroelectric polarization FD might not be sufficiently offset by the positive charges inside the capacitor dielectric layer 420a at the interface S1 between the capacitor dielectric layer 420a and the barrier dielectric layer 430a. Accordingly, the depolarization electric field, sufficient to suppress the ferroelectric polarization FD, may be easily formed in the barrier dielectric layer 430a having ferroelectricity. As a result, the dielectric structure 2001 may be effectively controlled to have substantially the same capacitance as the capacitor dielectric layer 420a. In addition, when an operating voltage is applied to the storage node electrode 410a in a state in which the plate electrode 440a is grounded, a relatively high electric field may be applied to the capacitor dielectric layer 420a that is disposed to be closer to the storage node electrode 410a, between the capacitor dielectric layer 420a and the barrier dielectric layer 430a. Accordingly, a relatively low electric field may be applied to the barrier dielectric layer 430a, so that the ferroelectric hysteresis behavior of the barrier dielectric layer 430a may be relatively mitigated. As a result, the dielectric structure 2001 may have the same dielectric characteristics as in the electric circuit of FIG. 4.

Although not illustrated in FIGS. 15A and 15B, in some embodiments, the semiconductor device 401 may further include a first interfacial insulation layer that is disposed between the capacitor dielectric layer 420a and the barrier dielectric layer 430a. The first interfacial insulation layer may correspond to the interfacial insulation layer 201 that is disposed between the ferroelectric layer 120 and the dielectric layer 130 in the semiconductor device 2, described with reference to FIG. 8.

Although not illustrated in FIGS. 15A and 15B, in some embodiments, the semiconductor device 401 may further include the first interfacial insulation layer that is disposed between the capacitor dielectric layer 420a and the barrier dielectric layer 430a, and a second interfacial insulation layer that is disposed between the capacitor dielectric layer 420a and the storage node electrode 410a. The first interfacial insulation layer and the second interfacial insulation layer may correspond to the first interfacial insulation layer 201 that is disposed between the ferroelectric layer 120 and the dielectric layer 130, and the second interfacial insulation layer 202 that is disposed between the dielectric layer 130 and the second electrode 140 in the semiconductor device 3, described with reference to FIG. 9, respectively.

Although not illustrated in FIGS. 15A and 15B, in some embodiments, the semiconductor device 401 may further include the first interfacial insulation layer that is disposed between the capacitor dielectric layer 420a and the barrier dielectric layer 430a, the second interfacial insulation layer that is disposed between the capacitor dielectric layer 420a and the storage node electrode 410a, and a third interfacial insulation layer that is disposed between the barrier dielectric layer 430a and the plate electrode 440a. The first interfacial insulation layer, the second interfacial insulation layer, and the third interfacial insulation layer may correspond to the first interfacial insulation layer 201 that is disposed between the ferroelectric layer 120 and the dielectric layer 130, the second interfacial insulation layer 202 that is disposed between the dielectric layer 130 and the second electrode 140, and the third interfacial insulation layer 204 that is disposed between the ferroelectric layer 120 and the first electrode 110 in the semiconductor device 5, described with reference to FIG. 11, respectively.

Although not illustrated in FIGS. 15A and 15B, in some embodiments, the semiconductor device 401 may further include a reduction sacrificial layer that is disposed between the second interfacial insulation layer and the storage node electrode 410a. The reduction sacrificial layer may correspond to the reduction sacrificial layer 203 that is disposed between the interfacial insulation layer 202 and the second electrode 140 in the semiconductor device 4, described with reference to FIG. 10.

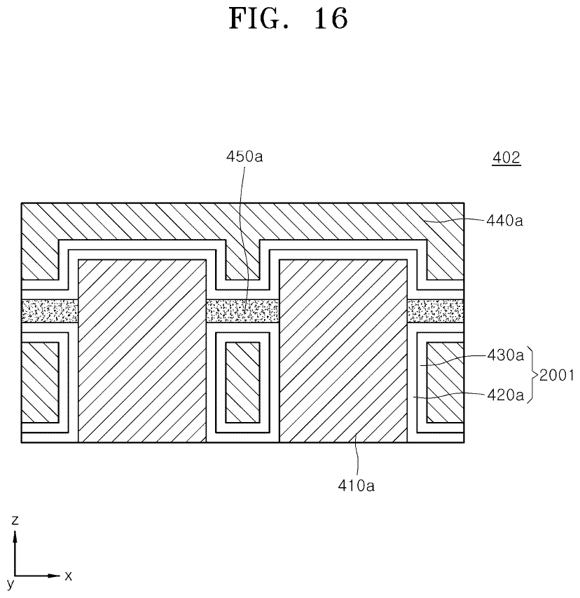

FIG. 16 is a cross-sectional view schematically illustrating a semiconductor device 402 according to another embodiment of the present disclosure. Referring to FIG. 16, besides the components of the semiconductor device 401 of FIGS. 15A and 15B, the semiconductor device 402 may further include supporters 450a that connect the storage node electrodes 410a to each other. The supporters 450a may serve to physically support the outer walls of the storage node electrodes 410a. The supporters 450a may improve the structural stability of the storage node electrodes 410a. Each of the supporters 450a may include, for example, silicon nitride. In FIG. 16, one supporter 450a may be disposed on the outer wall of each of the storage node electrodes 410a along a height direction (i.e., the z-direction) of the storage node electrode 410a, but the the present disclosure is not necessarily limited thereto. In some embodiments, two or more supporters may be disposed on the outer wall of each of the storage node electrodes 410a along the height direction (i.e., the z-direction) of the storage node electrode 410a.

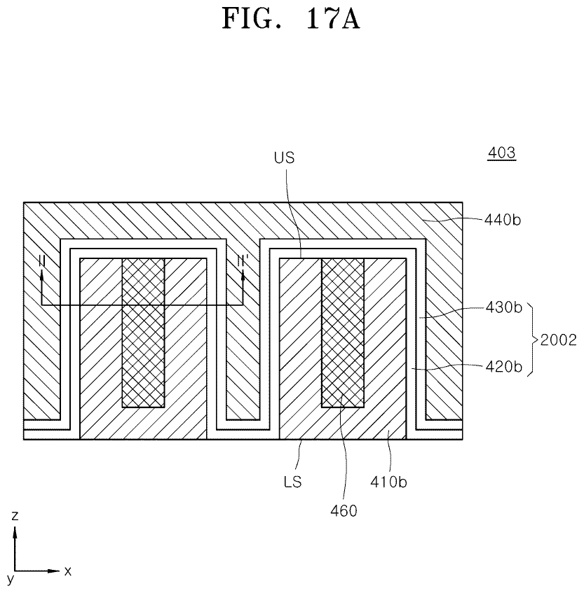

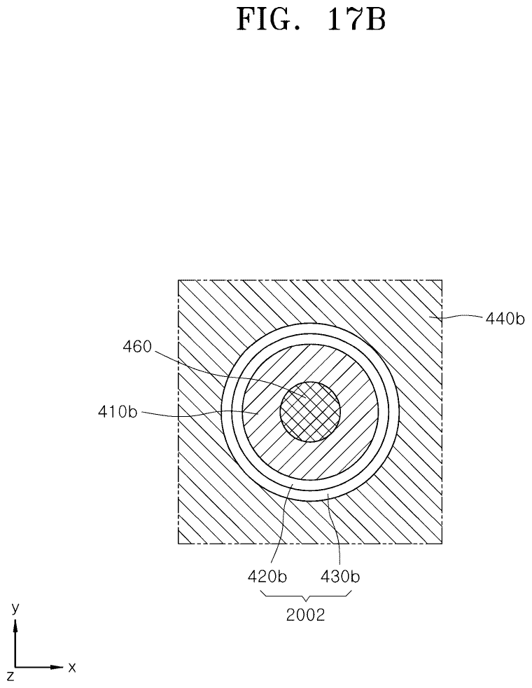

FIG. 17A is a cross-sectional view schematically illustrating a semiconductor device 403 according to further another embodiment of the present disclosure. FIG. 17B is a cross-sectional view of the semiconductor device 403 of FIG. 17A taken along line II-II′ and shown on the x-y plane. In an embodiment, the semiconductor device 403 may include a capacitor device. As an example, the semiconductor device 403 may be applied to the cell capacitor 400 of the memory cell 8 of FIGS. 14A to 14C.

Referring to FIGS. 17A and 17B, the semiconductor device 403 may be different from the semiconductor device 401, described with reference to FIGS. 15A and 15B in the configuration of a storage node electrode 410b. The configuration of the semiconductor device 403 may be substantially the same as the configuration of the semiconductor device 401 of FIGS. 15A and 15B, except for the storage node electrode 410b. That is, the configurations of a dielectric structure 2002 including a capacitor dielectric layer 420b and a barrier dielectric layer 430b, and the plate electrode 440b of the semiconductor device 403 may be substantially the same as the configurations of the dielectric structure 2002 including the capacitor dielectric layer 420a and the barrier dielectric layer 430a, and the plate electrode 440a of the semiconductor device 401 of FIGS. 15A and 15B, respectively.

Referring to FIGS. 17A and 17B, the storage node electrode 410b may include a filling structure 460 that fills a trench pattern formed in a pillar-shaped conductive structure. The filling structure 460 may be a pillar-shaped structure that has a predetermined cross-sectional area and extends in the z-direction. As an example, the filling structure 460 may have a cylindrical shape. However, in another example, the filling structure 460 may have a polygonal pillar shape.

In an embodiment, the filling structure 460 may include a silicon (Si) layer. The silicon (Si) layer may be doped to have conductivity. Alternatively, the silicon (Si) layer may have an un-doped state. In an embodiment, in order to form the filling structure 460, the pillar-shaped conductive structure, described above with reference to FIGS. 15A and 15B, may be formed, and then, the trench pattern may be formed in the conductive structure. The trench pattern may extend from an upper surface US of the pillar-shaped conductive structure to a lower surface LS. Subsequently, the trench pattern may be filled with silicon (Si) to form the filling structure 460.

Referring to FIGS. 17A and 17B, the dielectric structure 2002 and the plate electrode 440b may be sequentially disposed on the storage node electrode 410b including the filling structure 460. The capacitor dielectric layer 420b of the dielectric structure 2002 may be disposed on the storage node electrode 410b, and the barrier dielectric layer 430b may be disposed on the capacitor dielectric layer 420b.

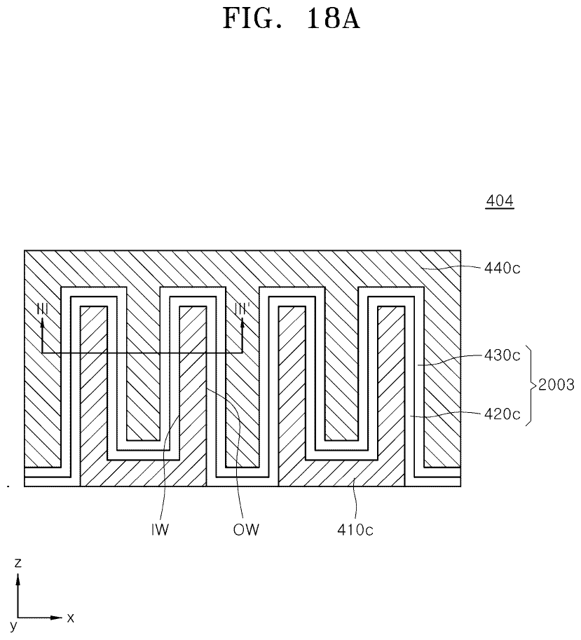

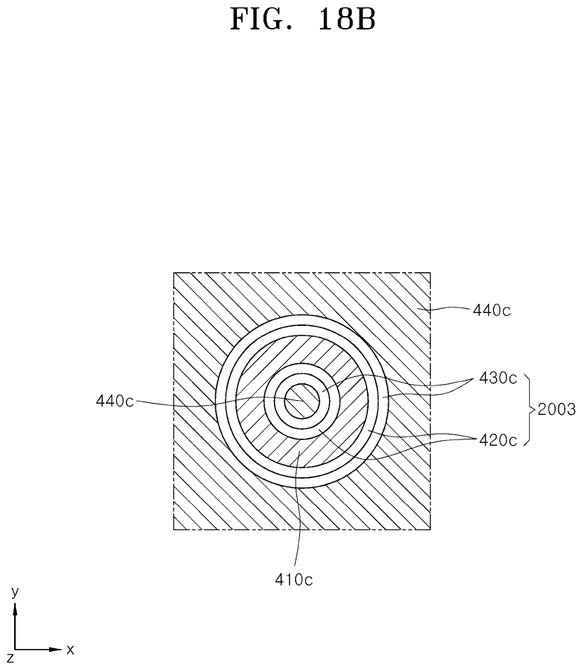

FIG. 18A is a cross-sectional view schematically illustrating a semiconductor device 404 according to further another embodiment of the present disclosure. FIG. 18B is a cross-sectional view of the semiconductor device 404 of FIG. 18A taken along line III-III′ and shown on the x-y plane. In an embodiment, the semiconductor device 404 may include a capacitor device. As an example, the semiconductor device 404 may be applied to the cell capacitor 400 of the memory cell 8 of FIGS. 14A to 14C.

Referring to FIG. 18A, the semiconductor device 404 may have a three-dimensional structure. The semiconductor device 404 may include a cylinder-shaped storage node electrode 410c, a dielectric structure 2003 that is disposed on the storage node electrode 410c, and a plate electrode 440c that is disposed on the dielectric structure 2003. The dielectric structure 2003 may include a capacitor dielectric layer 420c and a barrier dielectric layer 430c that are connected in series to each other. The capacitor dielectric layer 420c may include a non-ferroelectric material, and the barrier dielectric layer 430c may include a ferroelectric material. In the semiconductor device 404, the storage node electrode 410c may be an electrode to which an operating voltage is applied, and the plate electrode 440c may be a ground electrode.

The semiconductor device 404 may be different from the semiconductor device 401 of FIGS. 15A and 15B in the shape of the storage nod electrode 410c. The configuration of the semiconductor device 404, except for the shape of the storage node electrode 410c, may be substantially the same as the configuration of the semiconductor device 401 of FIGS. 15A and 15B. Referring to FIGS. 18A and 18B, the storage node electrode 410c may have a cylindrical shape. Accordingly, the capacitor dielectric layer 420c of the dielectric structure 2003 may be disposed to cover the inner wall surface IW and the outer wall surface OW of the storage node electrode 410c. The barrier dielectric layer 430c may be disposed on the capacitor dielectric layer 420c. The plate electrode 440c may be disposed to cover the barrier dielectric layer 430c.

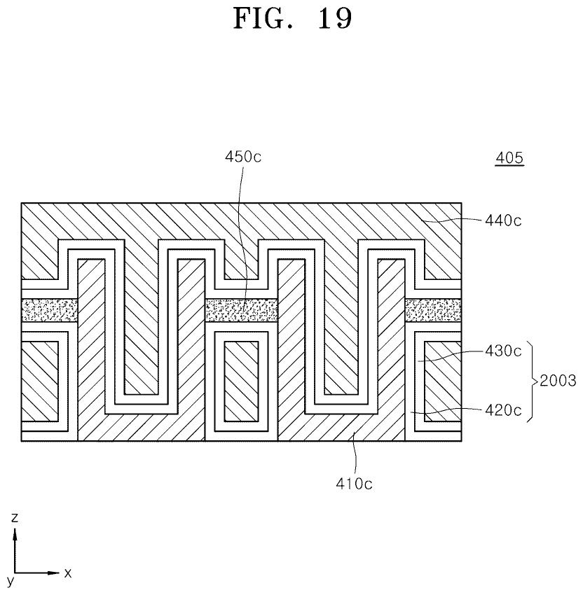

FIG. 19 is a cross-sectional view schematically illustrating a semiconductor device 405 according to further another embodiment of the present disclosure. Referring to FIG. 19, besides the components of the semiconductor device 404 of FIGS. 18A and 18B, the semiconductor device 405 may further include supporters 450c that connect the storage node electrodes 410c to each other. The supporters 450c may serve to physically support the outer walls of the storage node electrodes 410c. The supporters 450c may improve structural stability of the storage node electrodes 410c. Each of the supporters 450c may include, for example, silicon nitride. In FIG. 19, one supporter 450c may be disposed on the outer wall of each of the storage node electrodes 410c along the height direction (i.e., the z-direction) of the storage node electrode 410c, but the present disclosure is not necessarily limited thereto. In some embodiments, two or more supporters may be disposed on an outer wall of each of the storage node electrodes 410c along the height direction (i.e., the z-direction) of the storage node electrode 410c.

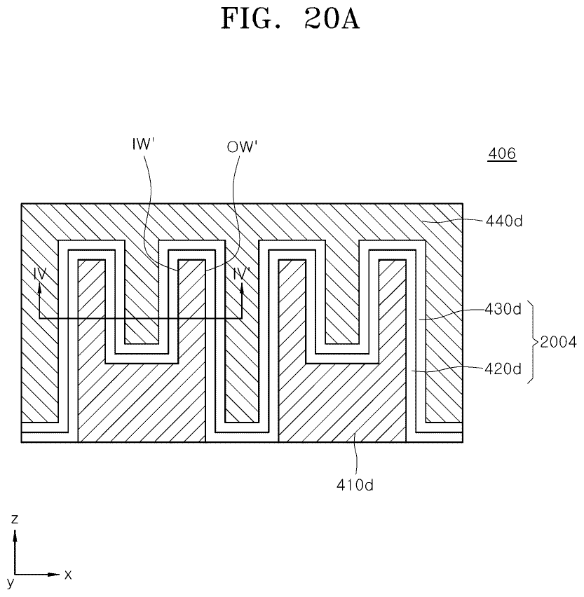

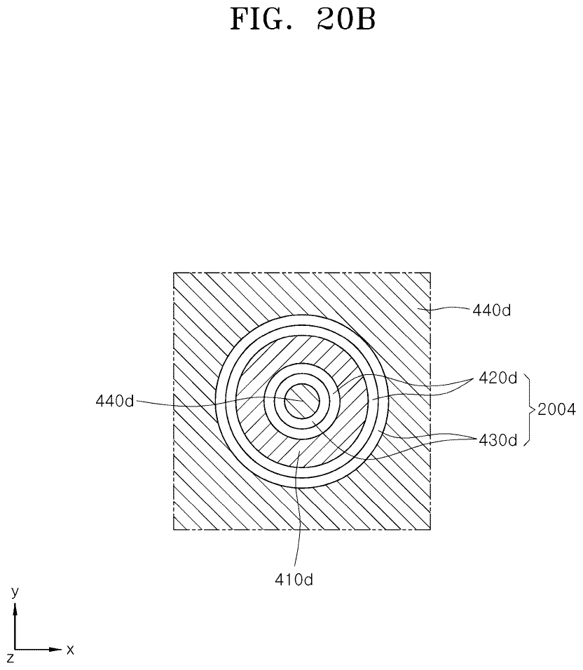

FIG. 20A is a cross-sectional view schematically illustrating a semiconductor device 406 according to further another embodiment of the present disclosure. FIG. 20B is a cross-sectional view of the semiconductor device 406 of FIG. 20A taken along line IV-IV′ and shown on the x-y plane. In an embodiment, the semiconductor device 406 may be applied to the cell capacitor 400 of the memory cell 8 of FIGS. 14A to 14C.

Referring to FIG. 20A, the semiconductor device 406 may include a three-dimensional structure. The semiconductor device 406 may include a storage node electrode 410d of a three-dimensional structure, a dielectric structure 2004 that is disposed on the storage node electrode 410d, and a plate electrode 440d that is disposed on the dielectric structure 2004. The dielectric structure 2004 may include a capacitor dielectric layer 420d and a barrier dielectric layer 430d that are connected in series to each other. The capacitor dielectric layer 420d may include a non-ferroelectric material, and the barrier dielectric layer 430d may include a ferroelectric material. In the semiconductor device 406, the storage node electrode 410d may be an electrode to which an operating voltage is applied, and the plate electrode 440d may be a ground electrode.

The semiconductor device 406 may be different from the semiconductor device 401 of FIGS. 15A and 15B in the shape of the storage node electrode 410d. The configuration of the semiconductor device 406, except for the shape of the storage node electrode 410d, may be substantially the same as the configuration of the semiconductor device 401 of FIGS. 15A and 15B. Referring to FIGS. 20A and 20B, the storage node electrode 410d may have a composite shape in which the pillar shape of the storage node electrode 410a, illustrated in FIGS. 15A and 15B, and the cylinder shape of the storage node electrode 410c, illustrated in FIGS. 18A and 18B, are combined. The capacitor dielectric 420d of the dielectric structure 2004 may be disposed to cover the inner wall surface IW′ and the outer wall surface OW′ of the storage node electrode 410d.

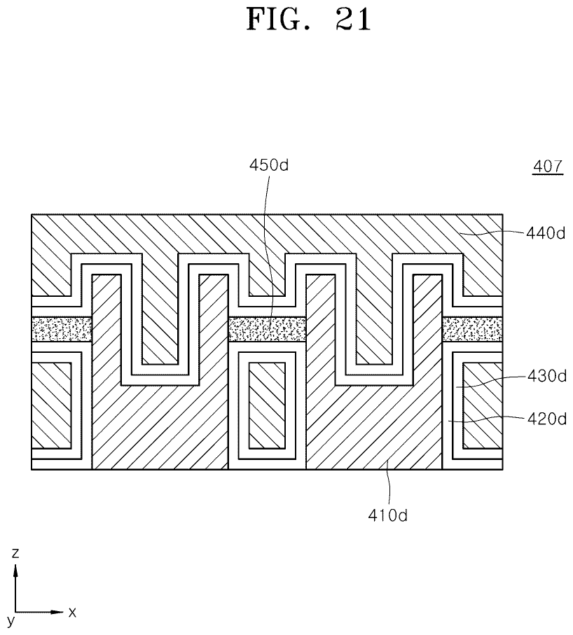

FIG. 21 is a cross-sectional view schematically illustrating a semiconductor device 407 according to further another embodiment of the present disclosure. Referring to FIG. 21, besides the components of the semiconductor device 406 of FIGS. 20A and 20B, the semiconductor device 407 may further include supporters 450d that connect storage node electrodes 410d. The supporters 450d may serve to physically support the outer walls of the storage node electrodes 410d. The supporters 450d may improve the structural stability of the storage node electrodes 410d. Each of the supporters 450d may include, for example, silicon nitride. In FIG. 21, one supporter 450d may be disposed on the outer wall of each of the storage node electrodes 410d along the height direction (i.e., the z-direction) of the storage node electrode 410d, but the present disclosure is not necessarily limited thereto. In some embodiments, two or more supporters may be disposed on the outer wall of each of the storage node electrodes 410d along the height direction (i.e., the z-direction) of the storage node electrode 410d.

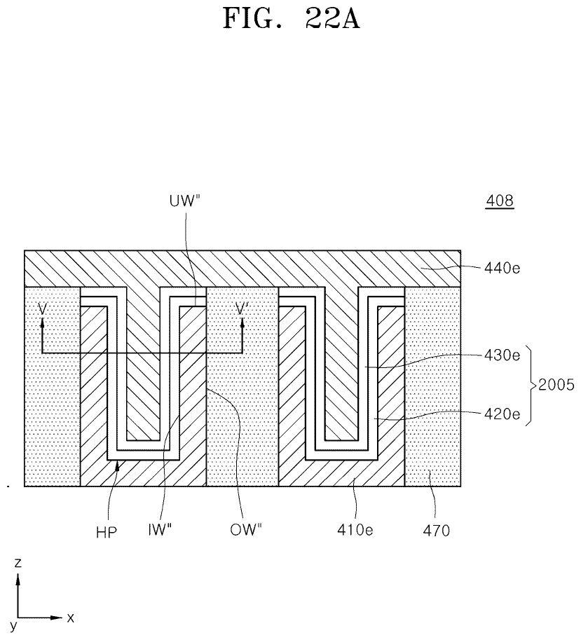

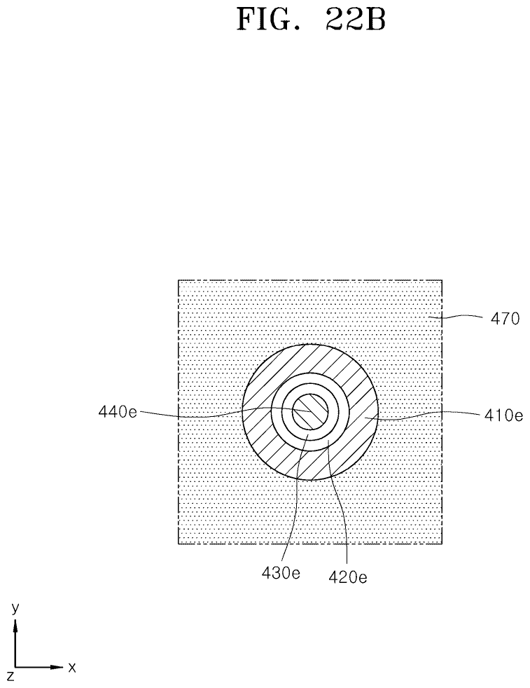

FIG. 22A is a cross-sectional view schematically illustrating a semiconductor device 408 according to further another embodiment of the present disclosure. FIG. 22B is a cross-sectional view of the semiconductor device 408 of FIG. 22A taken along line V-V′ and shown on the x-y plane. In an embodiment, the semiconductor device 408 may include a capacitor. As an example, the semiconductor device 408 may be applied to the cell capacitor 400 of the memory cell 8 of FIGS. 14A to 14C.

Referring to FIG. 22A, the semiconductor device 408 may include a concave-shaped storage node electrode 410e, a dielectric structure 2005 that is disposed on the storage node electrode 410e, and a plate electrode 440e that is disposed on the dielectric structure 2005. The dielectric structure 2005 may include a capacitor dielectric layer 420e and a barrier dielectric layer 430e that are connected in series to each other.

Referring to FIGS. 22A and 22B, the semiconductor device 408 may be different from the semiconductor device 401 of FIGS. 15A and 15B in the configuration of the storage node electrode 410e. The configuration of the semiconductor device 408, except for the storage node electrode 410e, may be substantially the same as the configuration of the semiconductor device 401 of FIGS. 15A and 15B.

The storage node electrode 410e may have a three-dimensional structure having a concave shape HP. In an embodiment, the dielectric structure 2005 may be disposed on an inner wall surface IW″ and an upper surface UW″ of the storage node electrode 410e. A device isolation layer 470 may be disposed on outer wall surface OW″ of the storage node electrode 410e. The device isolation layer 470 may insulate neighboring storage node electrodes 410e from each other.

In an embodiment, the capacitor dielectric layer 420e may be disposed on the inner wall surface IW″ and the upper surface OW″ of the storage node electrode 410e, and the barrier dielectric layer 430e may be disposed on the capacitor dielectric layer 420e. The plate electrode 440e may be disposed to cover the dielectric structure 2005.

As described above, according to various embodiments of the present disclosure, each of the semiconductor devices may include a dielectric structure including a barrier dielectric layer and a capacitor dielectric layer that are connected in series to each other. The capacitance of the dielectric structure may be controlled to have substantially the same value as the capacitance of the capacitor dielectric layer, so that the capacitor dielectric layer may function as a substantial information storage dielectric layer of the semiconductor device. The barrier dielectric layer may be a barrier layer having a predetermined thickness, and may function to prevent or alleviate the deterioration of leakage current and breakdown voltage characteristics of the dielectric structure. Accordingly, according to the embodiments of the present disclosure, it is possible to provide semiconductor devices capable of effectively securing a desired capacitance while preventing or alleviating the deterioration of leakage current and breakdown voltage characteristics.

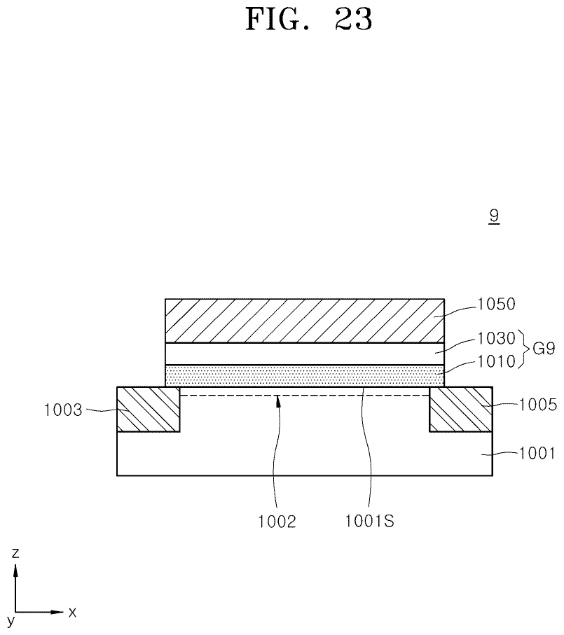

Meanwhile, in an embodiment of the present disclosure, the dielectric structure including the dielectric layer and the ferroelectric layer described above with reference to FIGS. 1 to 4 may be applied as a gate dielectric structure of a field effect transistor. The field effect transistors including the gate dielectric structure may be described in more detail through various embodiments with reference to FIGS. 23 to 25, 26A, 26B, 27A, 27B, 27C, 28A, 28B, and 28C below.

FIG. 23 is a cross-sectional view schematically illustrating a semiconductor device 9 including a gate dielectric structure according to an embodiment of the present disclosure. The semiconductor device 9 of FIG. 23 may include a field effect transistor.

Referring to FIG. 23, the semiconductor device 9 may include a substrate 1001 having a channel region 1002, a gate dielectric structure G9 that is disposed over the channel region 1002, and a gate electrode 1050 that is disposed on the gate dielectric structure G9. In addition, the semiconductor device 9 may include a source region 1003 and a drain region 1005 that are respectively disposed at opposite edges of the channel region 1002. The source region 1003 and the drain region 1005 may be portions of the substrate 1001.

The gate dielectric structure G9 may include a barrier dielectric layer 1010 and a gate dielectric layer 1030 that are connected in series to each other. The barrier dielectric layer 1010 may include a ferroelectric material, and the gate dielectric layer 1030 may include a non-ferroelectric material. The gate dielectric layer 1030 may have polarization characteristics, described above with reference to FIG. 2. The barrier dielectric layer 1010 may have the polarization characteristics, illustrated in FIG. 3, through bonding with the gate dielectric layer 1030. In an embodiment, the thickness of the barrier dielectric layer 1010 may be equal to or less than 5 nm, and the thickness of the barrier dielectric layer 1010 may be substantially the same as or thinner than the thickness of the gate dielectric layer 1030. In this case, when the thickness ratio between the barrier dielectric layer 1010 and the gate dielectric layer 1030 is distributed within a predetermined range, the barrier dielectric layer 1010 may have ferroelectric polarization characteristics in line with the graph of FIG. 3 as opposed to the graph of FIG. 1. In addition, the gate dielectric structure G9 including the barrier dielectric layer 1010 and the gate dielectric layer 1030 that are connected in series to each other with a thickness ratio within the predetermined range may have the non-ferroelectricity, described above with reference to FIG. 4.

Referring to FIG. 23, the substrate 1001 may be provided. The substrate 1001 may include a semiconductor material. Specifically, the semiconductor material may include silicon (Si), germanium (Ge), gallium arsenide (GaAs), or the like. The substrate 1001 may be doped with an n-type or p-type dopant to have predetermined conductivity. In an embodiment, the substrate 1001 may be a single crystalline silicon substrate that is doped with an n-type or p-type dopant.

The channel region 1002 may be a region of the substrate 1001 that is positioned directly below the gate dielectric structure G9. The channel region 1002 may be a region of the substrate 1001 in which a conductive channel is formed when a gate voltage equal to or greater than a threshold voltage is applied between the gate electrode layer 1050 and the substrate 1001. The conductive channel may electrically connect the source region 1003 and the drain region 1005 to each other. Accordingly, when a voltage is applied between the source region 1003 and the drain region 1005, electrical carriers, such as electrons or holes, may conduct through the conductive channel.

The barrier dielectric layer 1010 may be disposed over the channel region 1002. As illustrated in FIG. 23, the barrier dielectric layer 1010 may be disposed on a surface 1001S of the substrate 1001. The barrier dielectric layer 1010 may include a ferroelectric material. In an embodiment, the barrier dielectric layer 1010 may include a hafnium zirconium oxide layer. In another embodiment, the barrier dielectric layer 1010 may include a dopant that is doped in the hafnium zirconium oxide layer. The dopant may stabilize the ferroelectricity of the barrier dielectric layer 1010. The dopant may include, for example, carbon (C), silicon (Si), magnesium (Mg), aluminum (Al), yttrium (Y), nitrogen (N), germanium (Ge), tin (Sn), strontium (Sr)), lead (Pb), calcium (Ca), barium (Ba), titanium (Ti), zirconium (Zr), gadolinium (Gd), lanthanum (La), or a combination of two or more thereof.

In an embodiment, the barrier dielectric layer 1010 may have a crystal structure of an orthorhombic crystal system. The barrier dielectric layer 1010 may have a thickness of 1 nm to 5 nm, for example. The barrier dielectric layer 1010 may have a single crystalline structure or a polycrystalline structure. In an embodiment, the barrier dielectric layer 1010 may be an epi-growth layer. The barrier dielectric layer 1010 may be formed epitaxially over the channel region 1002 through, for example, atomic layer deposition, pulsed layer deposition, or chemical vapor deposition.

The gate dielectric layer 1030 may be disposed on the barrier dielectric layer 1010. The gate dielectric layer 1030 may have the non-ferroelectricity of the dielectric layer 20D, described above with reference to FIGS. 2 and 3. The gate dielectric layer 1030 may have paraelectricity, for example. The gate dielectric layer 1030 may have substantially the same dielectric characteristics as the dielectric layer 20D of the dielectric structure 40D, described with reference to FIG. 4.

The gate dielectric layer 1030 may include a non-ferroelectric material. In an embodiment, the gate dielectric layer 1030 may include hafnium oxide, zirconium oxide, or a combination thereof. The gate dielectric layer 1030 may have a crystal structure of a monoclinic crystal system or a tetragonal crystal system. The gate dielectric layer 1030 may have a thickness of 1 nm to 5 nm, for example.

In an embodiment, the gate dielectric layer 1030 may be an epi-growth layer. The gate dielectric layer 1030 may be epitaxially formed on the barrier dielectric layer 1010 through, for example, atomic layer deposition, pulsed layer deposition, or chemical vapor deposition.

The gate electrode 1050 may be disposed on the gate dielectric layer 1030. The gate electrode 1050 may include a conductive material. The conductive material may include, for example, doped silicon (Si), gold (Au), silver (Ag), tungsten (W), titanium (Ti), copper (Cu), aluminum (Al), ruthenium (Ru), platinum (Pt), iridium (Ir), iridium oxide, tungsten nitride, titanium nitride, tantalum nitride, tungsten carbide, titanium carbide, tungsten silicide, titanium silicide, tantalum silicide, ruthenium oxide, or a combination of two or more thereof.

Referring to FIG. 23 again, the source region 1003 and the drain region 1005 may be disposed to be spaced apart from each other. The source region 1003 and the drain region 1005 may be doped with a dopant of different doping type from the substrate 1001. As an example, when the substrate 1001 is doped with a p-type dopant, the source region 1003 and the drain region 1005 may be doped with an n-type dopant. As another example, when the substrate 1001 is doped with an n-type dopant, the source region 1003 and the drain region 1005 may be doped with a p-type dopant.

In some embodiments, the stacking order of the barrier dielectric layer 1010 and the gate dielectric layer 1030 over the channel region 1002 may be changed. That is, as an example, the gate dielectric layer 1030 may be disposed on the surface 1001S of the substrate 1001, and the barrier dielectric layer 1010 may be disposed on the gate dielectric layer 1030. The gate electrode 1050 may be disposed on the barrier dielectric layer 1010.

In some embodiments, an interfacial insulation layer may be disposed between the barrier dielectric layer 1010 and the gate dielectric layer 1030. The interfacial insulation layer may suppress or reduce material exchanges between the barrier dielectric layer 1010 and the gate dielectric layer 1030. Accordingly, the material composition of each of the barrier dielectric layer 1010 and the gate dielectric layer 1030 may be prevented or alleviated from being changed. In addition, the interfacial insulation layer may have a band gap energy that is greater than a band gap energy of each of the barrier dielectric layer 1010 and the gate dielectric layer 1030, thereby forming a potential barrier between the barrier dielectric layer 1010 and the gate dielectric layer 1030. The interfacial insulation layer may correspond to the interfacial insulation layer 201 of the semiconductor device 2, described with reference to FIG. 8.

In some embodiments, another interfacial insulation layer may be disposed between the gate dielectric layer 1030 and the gate electrode 1050. The another interfacial insulation layer that is disposed between the gate dielectric layer 1030 and the gate electrode 1050 may suppress or reduce material exchanges between the gate dielectric layer 1030 and the gate electrode 1050 and may form a potential barrier between the gate dielectric layer 1030 and the gate electrode 1050. In addition, further another interfacial insulation layer may be disposed between the substrate 1001 and the barrier dielectric layer 1010. The further another interfacial insulation layer that is disposed between the substrate 1001 and the barrier dielectric layer 1010 may suppress or reduce material exchanges between the substrate 1001 and the barrier dielectric layer 1010, and may form a potential barrier between the substrate 1001 and the barrier dielectric layer 1010. The another interfacial insulation layer that is disposed between the gate dielectric layer 1030 and the gate electrode 1050 and the further another interfacial insulation layer that is disposed between the substrate 1001 and the barrier dielectric layer 1010 may correspond to the second and third interfacial insulation layers 202 and 204 of the semiconductor device 5 described with reference to FIG. 11, respectively.

As described above, according to the embodiments of the present disclosure, the gate dielectric structure of a semiconductor device may include a barrier dielectric layer and a gate dielectric layer that are connected in series to each other. The barrier dielectric layer may include a ferroelectric material, and the gate dielectric layer may include a non-ferroelectric material. The capacitance of the gate dielectric structure may be controlled to have substantially the same value as the capacitance of the gate dielectric layer. The barrier dielectric layer may be a barrier layer having a predetermined thickness and may function to prevent or alleviate the deterioration of leakage current and breakdown voltage characteristics of the gate dielectric structure. Accordingly, according to the embodiments of the present disclosure, it is possible to provide a semiconductor device including a gate dielectric structure capable of effectively securing a desired capacitance while preventing or alleviating the deterioration of the leakage current and breakdown voltage characteristics.

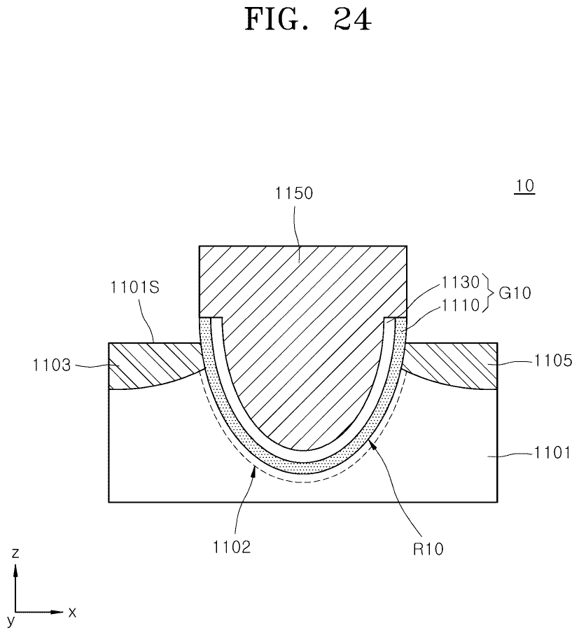

FIG. 24 is a cross-sectional view schematically illustrating a semiconductor device 10 including a gate dielectric structure G10 according to an embodiment of the present disclosure. The semiconductor device 10 of FIG. 24 may include a field effect transistor. The semiconductor device 10 of FIG. 24 may be different from the semiconductor device 9 of FIG. 23 in the configurations of the gate dielectric structure G10 and a gate electrode 1150.

Referring to FIG. 24, the semiconductor device 10 may include a substrate 1101, a recess space R10 that is formed in the substrate 1101, the gate dielectric structure G10 that is disposed in the recess space R10, and the gate electrode 1150 that is disposed on the gate dielectric structure G10. The gate dielectric structure G10 may include a barrier dielectric layer 1110 and a gate dielectric layer 1130. In addition, the semiconductor device 10 may include a source region 1103 and a drain region 1105 that are disposed in regions of the substrate 1101, located at opposite sides of the recess space R10. In this case, a channel region 1102 of the semiconductor device 10 may be formed in an inner region of the substrate 1101 along an interface with the gate dielectric structure G10.

The material composition of the substrate 1101, the source region 1103, the drain region 1105, the gate dielectric structure G10, and the gate electrode 1150 may be substantially the same as the material composition of the substrate 1001, the source region 1003, the drain region 1005, the gate dielectric structure G9, and the gate electrode 1050, described above with reference to FIG. 23.

However, in the semiconductor device 9 of FIG. 23, the gate dielectric structure G9 and the gate electrode 1050 may be disposed on the substrate 1001, whereas in the semiconductor device 10 of FIG. 24, a portion of each of the gate dielectric structure G10 and the gate electrode 1150 may be disposed in the recess region R10 that is formed into the substrate 1101 from the surface 1101S of the substrate 1101. In addition, another portion of each of the gate dielectric structure G10 and the gate electrode 1150 may be located over the surface 1101S of the substrate 1101. Compared to the semiconductor device 9 of FIG. 23, the semiconductor device 10 may include the recess region R10, so that it is possible to secure a relatively increased channel region 1102.

In an embodiment, in the gate dielectric structure G10, the barrier dielectric layer 1110 may be disposed closer to the channel region 1102 than the gate dielectric layer 1130. Accordingly, the barrier dielectric layer 1110 may be disposed along an inner wall of the recess region R10, and the gate dielectric layer 1130 may be disposed on the barrier dielectric layer 1110. Referring to FIG. 24, the gate electrode 1150, the gate dielectric layer 1130, and the barrier dielectric layer 1110 may be respectively disposed to have convex-curved surfaces based on the recess region R10. The barrier dielectric layer 1110 having ferroelectricity may be disposed to surround the convex curved surface of the gate dielectric layer 1130, having non-ferroelectricity with respect to the gate electrode 1150, so that the electrical charges that are formed by the spontaneous polarization of the barrier dielectric layer 1110 might not be sufficiently canceled by the electrical charges inside the gate dielectric layer 1130, as described above with reference to FIG. 15B. Accordingly, a depolarization electric field that is sufficient in suppressing the spontaneous polarization may be formed in the barrier dielectric layer 1110 having ferroelectricity. As a result, the gate dielectric structure G10 may be effectively controlled to have a capacitance that is substantially equal to the capacitance of the gate dielectric layer 1130.

In an embodiment, the semiconductor device 10 of FIG. 24 may be applied to the transistor of the memory cell 8, described above with reference to FIGS. 14A to 14C. The substrate 1101, the source region 1103, the drain region 1105, the gate dielectric structure G10, and the gate electrode 1150 of the semiconductor device 10 may correspond to the substrate 301, the first doping region 310, the second doping region 311, the gate insulation layer 307, and the gate electrode 308 of the semiconductor device 8 of FIGS. 14A to 14C, respectively.

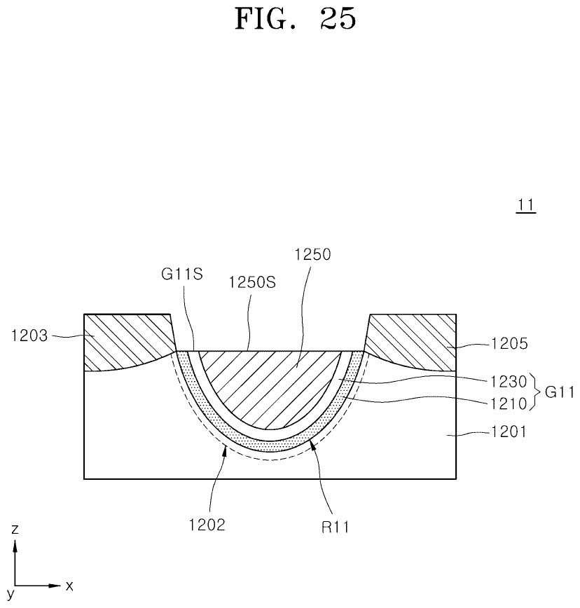

FIG. 25 is a cross-sectional view schematically illustrating a semiconductor device 11 including a gate dielectric structure G11 according to further another embodiment of the present disclosure. The semiconductor device 11 of FIG. 25 may include a field effect transistor. The semiconductor device 11 of FIG. 25 may be different from the semiconductor device 9 of FIG. 23 in the configurations of the gate dielectric structure G11 and a gate electrode 1250.

Referring to FIG. 25, the semiconductor device 11 may include a substrate 1201, a recess space R11 that is formed in the substrate 1201, the gate dielectric structure G11 that is disposed in the recess space R11, and the gate electrode 1250 that is disposed on the gate dielectric structure G11 in the recess space R11. The gate dielectric structure G11 may include a barrier dielectric layer 1210 and a gate dielectric layer 1230. In addition, the semiconductor device 11 may include a source region 1203 and a drain region 1205 that are disposed in the regions of the substrate 1201 at opposite edges of the recess space R11. In this case, a channel region 1202 of the semiconductor device 11 may be formed in an inner region of the substrate 1201 along an interface with the gate dielectric structure G11.

The material composition of the substrate 1201, the source region 1203, the drain region 1205, the gate dielectric structure G11, and the gate electrode 1250 may be substantially the same as the material composition of the substrate 1001, the source region 1003, the drain region 1005, the gate dielectric structure G9, and the gate electrode 1050, described above with reference to FIG. 23, respectively.

However, in the semiconductor device 9 of FIG. 23, the gate dielectric structure G9 and the gate electrode 1050 may be disposed on the substrate 1001, whereas in the semiconductor device 11 of FIG. 25, all of the gate dielectric structure G11 and the gate electrode 1250 may be disposed in the recess space R11 that is formed into the substrate 1201 from the surface 1201S of the substrate 1201. Accordingly, an upper surface G11S of the gate dielectric structure G11 and an upper surface 1250S of the gate electrode 1250 may be positioned at a lower level than the surface 1201S of the substrate 1201. Compared to the semiconductor device 9 of FIG. 23, the semiconductor device 11 may include the recess space R11, so that it is possible to secure the relatively increased channel region 1202.

In an embodiment, in the gate dielectric structure G11, the barrier dielectric layer 1210 may be disposed to be closer to the channel region 1202 than the gate dielectric layer 1230. Accordingly, the barrier dielectric layer 1210 may be disposed along an inner wall surface of the recess region R11, and the gate dielectric layer 1230 may be disposed on the barrier dielectric layer 1210. Referring to FIG. 25, the gate electrode 1250, the gate dielectric layer 1230, and the barrier dielectric layer 1210 may be disposed to have convex-curved surfaces toward the recess region R11. With respect to the gate electrode 1250, the barrier dielectric layer 1210 having ferroelectricity may be disposed to surround the gate dielectric layer 1230 having non-ferroelectricity so that the magnitude of the depolarization electric field in the barrier dielectric layer 1210 having ferroelectricity may be increased, as described above with reference to FIG. 15B. Accordingly, controlling the capacitance of the gate dielectric structure G11 to be the same as the capacitance of the gate dielectric layer 1230 may be more effectively performed.

In an embodiment, the semiconductor device 11 of FIG. 25 may be applied to the transistor of the memory cell 8, described above with reference to FIGS. 14A to 14C. The substrate 1201, the source region 1203, the drain region 1205, the gate dielectric structure G11, and the gate electrode 1250 of the semiconductor device 11 may correspond to the substrate 301, the first doping region 310, the second doping region 311, the gate dielectric layer 307, and the gate electrode 308 of the semiconductor device 10 of FIGS. 14A to 14C, respectively.

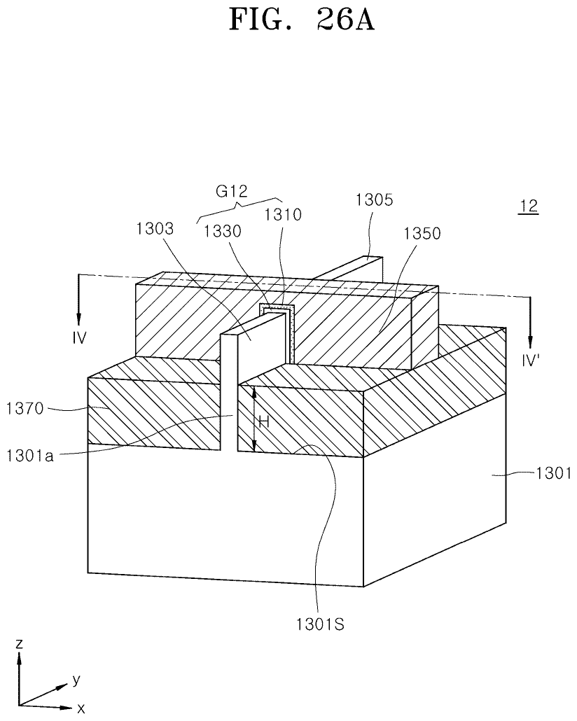

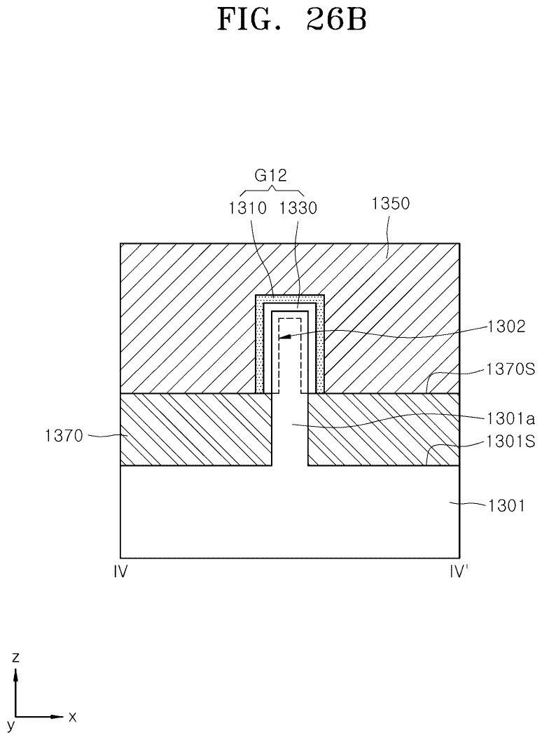

FIG. 26A is a perspective view schematically illustrating a semiconductor device 12 according to further another embodiment of the present disclosure. FIG. 26B is a cross-sectional view of the semiconductor device 12 of FIG. 26A taken along line IV-IV′. In an embodiment, the semiconductor device 12 of FIGS. 26A and 26B may include a transistor of a three-dimensional structure. In addition, the semiconductor device 12 may include a conductive channel formed in a fin structure that is an active layer.

Referring to FIGS. 26A and 26B, the semiconductor device 12 may include a fin structure 1301a, extending in a direction (e.g., the z-direction) that is substantially perpendicular to a surface 1301S of a substrate 1301, a base insulation layer 1370 that is disposed on the substrate 1301 to cover a portion of the fin structure 1301a, a gate dielectric structure G12 that is disposed on the base insulation layer 1370 to cover a portion of the fin structure 1301a, and a gate electrode 1350 that is disposed over the base insulation layer 1370 to cover the gate dielectric structure G12. The gate dielectric structure G12 may include a barrier dielectric layer 1310 and a gate dielectric layer 1330 that are connected in series to each other. The barrier dielectric layer 1310 may include a ferroelectric material, and the gate dielectric layer 1330 may include a non-ferroelectric material. In addition, the semiconductor device 12 may include a source region 1303 and a drain region 1305 that are formed in different portions of the fin structure 1301a.

The substrate 1301 may include a semiconductor material. The substrate 1301 may be doped with an n-type or p-type dopant. The fin structure 1301a may be disposed on the substrate 1301 to extend in a direction (e.g., the z-direction) that is perpendicular to the surface 1301S of the substrate 1301 and in a direction (e.g., the y-direction) that is parallel to the surface 1301S of the substrate 1301. The fin structure 1301a may be made of substantially the same material as the substrate 1301. In an embodiment, the fin structure 1301a may be formed by patterning the substrate 1301. The fin structure 1301a may correspond to an active layer for the electrical switching operation of the semiconductor device 12.

The base insulation layer 1370 may be disposed on the substrate 1301 to cover the fin structure 1301a by a predetermined height H. The base insulation layer 1370 may include, for example, oxide, nitride, oxynitride, or a combination of two or more thereof.

A portion of the fin structure 1301a, protruding above the base insulation layer 1370, may be covered by the gate dielectric structure G12 and the gate electrode 1350. Referring to FIG. 26B, the portion of the fin structure 1301a, covered by the gate dielectric structure G12 and the gate electrode 1350, may correspond to the channel region 1302.

In an embodiment, the gate dielectric structure G12 may have substantially the same dielectric characteristics as the gate dielectric structure G9 of the semiconductor device 9, described above with reference to FIG. 23. That is, the gate dielectric layer 1330 may have the polarization characteristics, described above with reference to FIG. 2. The barrier dielectric layer 1310 may have the polarization characteristics, illustrated in FIG. 3, through bonding with the gate dielectric layer 1330. In an embodiment, the thickness of the barrier dielectric layer 1310 may be 5 nm or less, and the thickness of the barrier dielectric layer 1310 may be substantially the same as or thinner than the thickness of the gate dielectric layer 1330. In this case, when the thickness ratio between the barrier dielectric layer 1310 and the gate dielectric layer 1330 is distributed within a predetermined range, the barrier dielectric layer 1310 may have ferroelectric polarization characteristics in line with the graph of FIG. 3 rather than the graph of FIG. 1. In addition, the gate dielectric structure G12 including the barrier dielectric layer 1310 and the gate dielectric layer 1330 having the thickness ratio within the predetermined range and connected in series to each other may have non-ferroelectricity, described above with reference to FIG. 4.

In an embodiment, the gate dielectric layer 1330 may be disposed to surround the channel region 1302 of the fin structure 1301a on the base insulation layer 1370, and the barrier dielectric layer 1310 may be disposed to cover the gate dielectric layer 1330. Referring to FIG. 26B, the fin structure 1301a, the gate dielectric layer 1330, and the barrier dielectric layer 1310 may be disposed to protrude upward (i.e., the z-direction) from a surface 1370S of the base insulation layer 1370. Based on the protruding fin structure 1301a, the barrier dielectric layer 1310 having ferroelectricity may be disposed to surround the protruding portion of the gate dielectric layer 1330 having non-ferroelectricity. Accordingly, the electrical charges that are formed by the spontaneous polarization of the barrier dielectric layer 1310 might not be sufficiently canceled by the electrical charges inside the gate dielectric layer 1330 as described above with reference to FIG. 15B. Accordingly, the depolarization electric field that is sufficient in suppressing the spontaneous polarization may be formed in the barrier dielectric layer 1310. As a result, the gate dielectric structure G12 may be effectively controlled to have a capacitance substantially equal to the capacitance of the gate dielectric layer 1330.

Referring to FIGS. 26A and 26B again, the portion of the fin structure 1301a protruding above the base insulation layer 1370, other than the channel region 1302, may be doped with an n-type or p-type dopant to be converted into the source region 1303 and the drain region 1305. In an embodiment, when the fin structure 1301a is doped with a p-type dopant, the source region 1303 and the drain region 1305 may be doped with an n-type dopant.

When a gate voltage that is equal to or greater than a threshold voltage is applied between the gate electrode 1350 and the fin structure 1301a, a conductive channel may be formed in the channel region 1302. The conductive channel may be formed in an inner region of the fin structure 1301a that forms an interface with the gate dielectric layer 1330. The conductive channel may electrically connect the source region 1303 and the drain region 1305 to each other. Then, when an operating voltage is applied between the source region 1303 and the drain region 1305, conductive carriers, such as electrons or holes, may conduct between the source region 1303 and the drain region 1305 through the conductive channel. In the embodiment of the present disclosure, the conductive channel may be implemented in the fin structure 1301a that protrudes in a three-dimensional structure, thereby increasing the volume of the conductive channel. As a result, the density of the conductive carriers that conduct through the conductive channel may increase, thereby increasing the channel current of the semiconductor device 12.

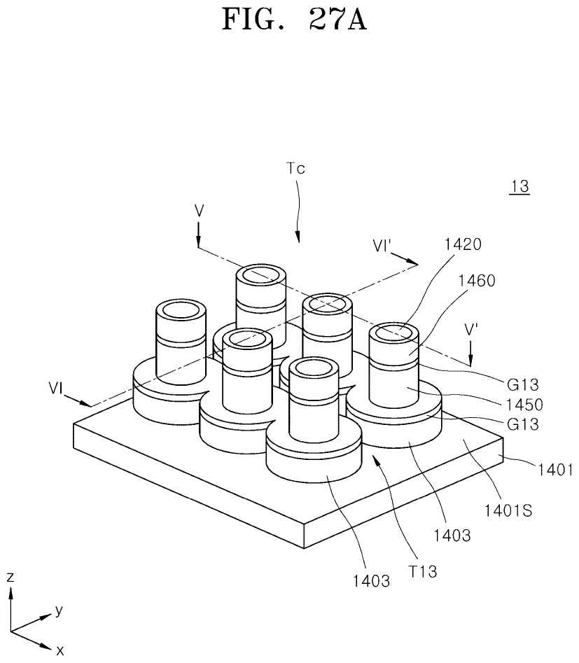

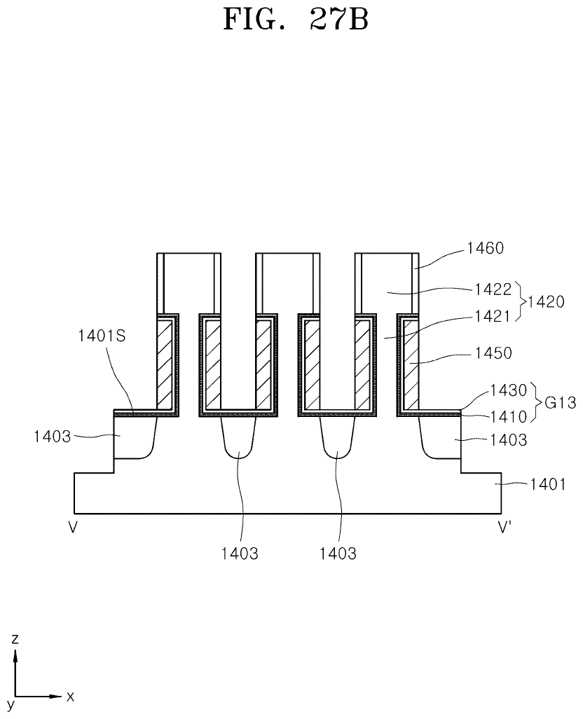

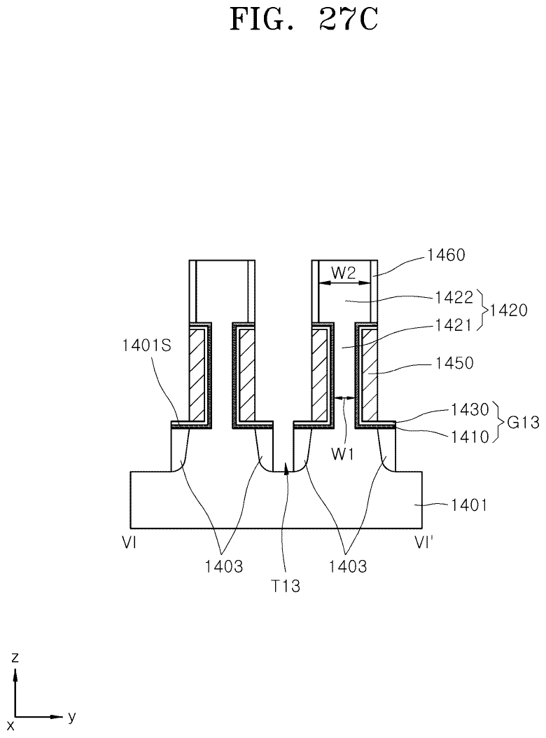

FIG. 27A is a perspective view schematically illustrating a semiconductor device 13 according to yet another embodiment of the present disclosure. FIG. 27B is a cross-sectional view of the semiconductor device 13 taken along line V-V′ of FIG. 27A. FIG. 27C is a cross-sectional view of the semiconductor device 13 taken along line VI-VI′ of FIG. 27A. In an embodiment, the semiconductor device 13 of FIGS. 27A to 27C may include transistors Tc of a three-dimensional structure having a vertical channel over a substrate 1401. For the convenience of description, an insulation layer surrounding the illustrated components of the semiconductor device 13 is omitted in FIGS. 27A to 27C.

Referring to FIGS. 27A to 27C, the semiconductor device 13 may include a plurality of transistors Tc that is disposed over the substrate 1401. The plurality of transistors Tc may be electrically separated from each other by separation trenches T13 that are formed in the substrate 1401.

Each of the plurality of transistors Tc may include the substrate 1401, an active pillar structure 1420 extending in a direction (e.g., the z-direction) substantially perpendicular to a surface 1410S of the substrate 1401, a gate dielectric structure G13 that is disposed to surround an outer surface of the active pillar structure 1420, and a gate electrode 1450 that is disposed on the gate dielectric structure G13. The gate dielectric structure G13 may include a barrier dielectric layer 1410 and a gate dielectric layer 1430 that are connected in series to each other. The barrier dielectric layer 1410 may include a ferroelectric material, and the gate dielectric layer 1430 may include a non-ferroelectric material. In addition, the semiconductor device 13 may include bit lines 1403 buried in the substrate 1401.

The substrate 1401 may include a semiconductor material. The substrate 1410 may be doped with an n-type and p-type dopant. In an embodiment, a portion of the substrate 1401 may be doped with a dopant to form the bit lines 1403. In an embodiment, the bit lines 1403 may be formed, for example, by doping the substrate 1401 through ion implantation. In an embodiment, when the substrate 1401 is doped into p-type, the bit lines 1403 may be doped into n-type.

Each of the active pillar structures 1420 may correspond to an active layer for an electrical switching operation of the semiconductor device 13. Each of the active pillar structures 1420 may include first and second pillar portions 1421 and 1422 respectively having different diameters on a cross-section cut in a direction that is substantially parallel to the surface 1401S of the substrate 1401. A diameter W1 of the first pillar portion 1421 may be smaller than a diameter W2 of the second pillar portion 1422. The active pillar structure 1420 may function as a channel region of the transistor Tc. The active pillar structures 1420 may be made of substantially the same material as the substrate 1401. In an embodiment, the substrate 1401 and the active pillar structures 1420 may be doped into p-type.

Referring to FIGS. 27A to 27C, the gate dielectric structure G13 may be disposed to surround the first pillar portion 1421 of the active pillar structure 1420. In an embodiment, the gate dielectric structure G13 may have dielectric characteristics that are substantially the same as that of the gate dielectric structure G9 of the semiconductor device 9, described above with reference to FIG. 23. That is, the gate dielectric layer 1430 may have polarization characteristics, described above with reference to FIG. 2. The barrier dielectric layer 1410 may have the polarization characteristics, illustrated in FIG. 3, through bonding with the gate dielectric layer 1430. In an embodiment, the thickness of the barrier dielectric layer 1410 is 5 nm or less, and the thickness of the barrier dielectric layer 1410 may be substantially the same as or thinner than the thickness of the gate dielectric layer 1430. In this case, when the thickness ratio between the barrier dielectric layer 1410 and the gate dielectric layer 1430 is distributed within a predetermined range, the barrier dielectric layer 1410 may have ferroelectric polarization characteristics according to the graph of FIG. 3 rather than the graph of FIG. 1. In addition, the gate dielectric structure G13 including the barrier dielectric layer 1410 and the gate dielectric layer 1430, connected in series with a thickness ratio within the predetermined range, may have the non-ferroelectricity, described above with reference to FIG. 4.

In an embodiment, the barrier dielectric layer 1410 may be disposed to cover an outer wall of the first pillar portion 1421, and the gate dielectric layer 1430 may be disposed on the barrier dielectric layer 1410. The gate electrode 1450 may be disposed on the gate dielectric layer 1430. The material composition of the barrier dielectric layer 1410, the gate dielectric layer 1430, and the gate electrode 1450 may be substantially the same as the material composition of the barrier dielectric layer 1310, the gate dielectric layer 1330, and the gate electrode 1350 of the semiconductor device 12 of FIGS. 26A and 26B, respectively.

Referring to FIG. 27B again, based on the gate electrode 1450, the barrier dielectric layer 1410 having ferroelectricity may be disposed to surround the gate dielectric layer 1430 having non-ferroelectricity. Through the arrangement of the barrier dielectric layer 1410 and the gate dielectric layer 1430, the electrical charges that are formed by the spontaneous polarization of the barrier dielectric layer 1410 might not be sufficiently canceled by the electrical charges inside the gate dielectric layer 1430, as described above with reference to FIG. 15B. Accordingly, the depolarization electric field sufficient in suppressing the spontaneous polarization may be formed in the barrier dielectric layer 1410. As a result, the gate dielectric structure G13 may be effectively controlled to have a capacitance that is substantially equal to the capacitance of the gate dielectric layer 1430. Referring back to FIGS. 27A to 27C, each of the bit lines 1403 may function as a source electrode for the first pillar portion 142 that is a channel region.

Referring to FIGS. 27A to 27C, the second pillar portion 1422 may be disposed on the first pillar portion 1421 of each of the active pillar structures 1420. An insulation spacer 1460 may be disposed on an outer wall surface of the second pillar portion 1422. Although not illustrated, a source line may be disposed on the second pillar portion 1422. The source line may function as a drain electrode for the second pillar portion 1422.

According to the embodiment of the present disclosure, the channel region of the transistor may be formed in the active pillar structure 1420, extending in a direction (e.g., the z-direction) that is substantially perpendicular to the surface 1401S of the substrate 1401. The gate dielectric structure G13 and the gate electrode 1450 may be disposed to surround the outer wall surface of the active pillar structure 1420, so that the conductive channel may be formed in a direction (e.g., the z-direction) substantially perpendicular to the surface 1401S of the substrate 1401 in the channel region. Accordingly, the area of the channel region of the transistor may be effectively secured.

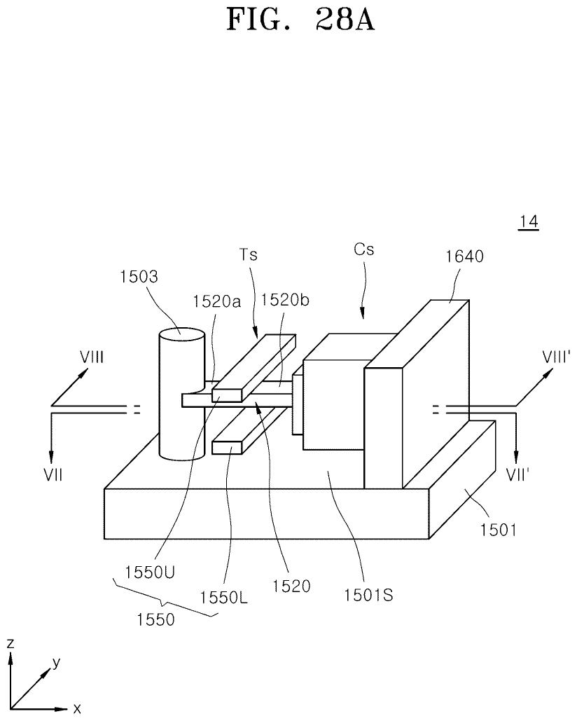

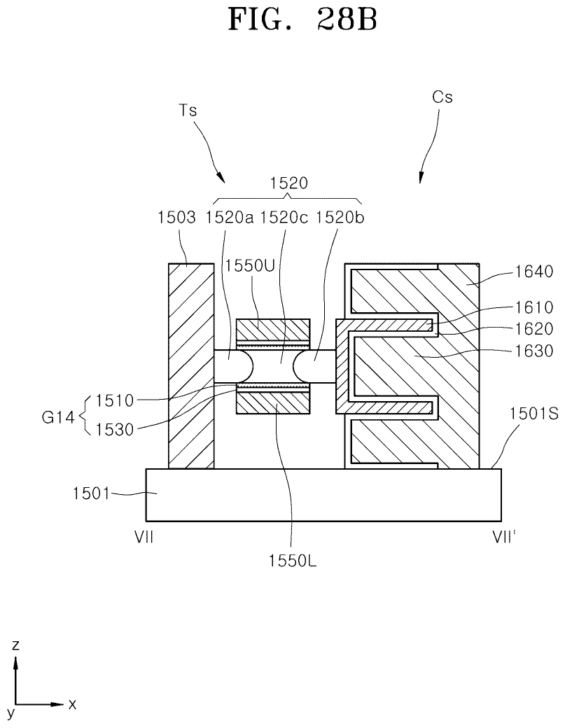

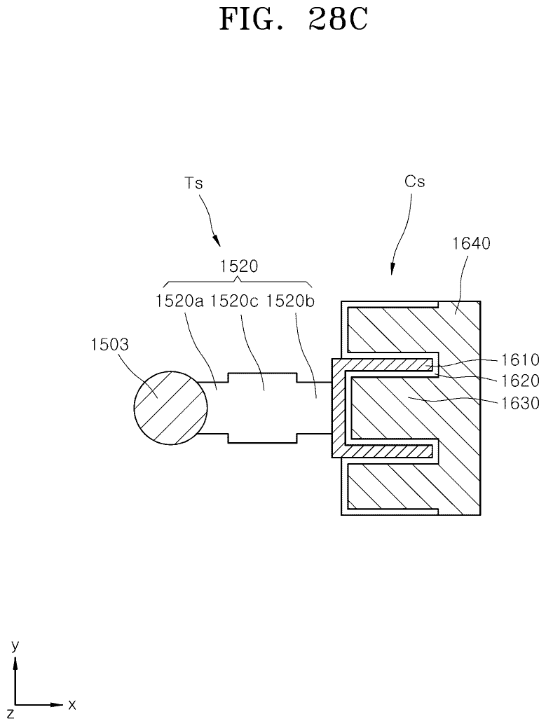

FIG. 28A is a perspective view schematically illustrating a semiconductor device 14 according to still yet another embodiment of the present disclosure. FIG. 28B is a cross-sectional view of the semiconductor device 14 taken along line VII-VII′ of FIG. 28A. FIG. 28C is a cross-sectional view of the semiconductor device 14 taken along line VIII-VIII′ of FIG. 28A. In an embodiment, the semiconductor device 14 of FIGS. 28A to 28C may include a base structure 1501 and a transistor Ts having a three-dimensional structure that is disposed on the base structure 1501. In addition, the semiconductor device 14 may include a capacitor Cs that is electrically connected to the transistor Ts over the base structure 1501. For convenience of description, an insulation layer surrounding the illustrated components of the semiconductor device 14 has been omitted in FIGS. 28A to 28C.

Referring to FIGS. 28A to 28C, the semiconductor device 14 may include the base structure 1501. The base structure 1501 may include a substrate. In addition, the base structure 1501 may include at least one conductive layer and at least one interlayer insulation layer that are disposed on the substrate. The base structure 1501 may serve to support the transistor Ts and the capacitor Cs of the semiconductor device 14. The substrate may include a semiconductor material.

The transistor Ts of the semiconductor device 14 may include an active layer 1520 that is disposed over the base structure 1501, a gate dielectric structure G14 that is disposed on an upper surface and a lower surface of the active layer 1520, and a gate electrode 1550 that is disposed on the gate dielectric structure G14. The capacitor Cs of the semiconductor device 14 may include a storage node electrode 1610, an information storage dielectric layer 1620, and a plate electrode 1630 that are disposed over the base structure 1501.

The active layer 1520 may be disposed on a plane that is substantially parallel to a surface 1501S of the base structure 1501. Although not illustrated, the surface 1501S of the base structure 1501 may be a plane that is substantially parallel to the surface of the substrate. The active layer 1520 may include a source region 1520a and a drain region 1520b that are spaced apart from each other. In addition, the active layer 1520 may include a channel region 1520c between the source region 1520a and the drain region 1520b. The upper and lower surfaces of the channel region 1520c may be covered by the gate dielectric structure G14.

The active layer 1520 may include a semiconductor material. The semiconductor material may include silicon (Si), germanium (Ge), gallium arsenide (GaAs), or the like. The active layer 1520 may be doped with an n-type or p-type dopant. In an embodiment, the source region 1520a and the drain region 1520b may be doped with an n-type dopant, and the channel region 1520c may be doped with a p-type dopant. In another embodiment, the source region 1520a and the drain region 1520b may be doped with a p-type dopant, and the channel region 1520c may be doped with an n-type dopant. The channel region 1520c may extend in a direction (e.g., the x-direction) substantially parallel to the surface 1501S of the base structure 1501.

The gate dielectric structure G14 may be disposed on the upper surface and the lower surface of the active layer 1520. Referring to FIG. 28B, the gate dielectric structure G14 may include a barrier dielectric layer 1510 and a gate dielectric layer 1530 that are connected in series to each other. The barrier dielectric layer 1510 may include a ferroelectric material, and the gate dielectric layer 1530 may include a non-ferroelectric material. As illustrated, the barrier dielectric layer 1510 may be disposed on the channel region 1520c, and the gate dielectric layer 1530 may be disposed on the barrier dielectric layer 1510.

In an embodiment, the gate dielectric structure G14 may have substantially the same dielectric characteristics as the gate dielectric structure G9 of the semiconductor device 9, described above with reference to FIG. 23. That is, the gate dielectric layer 1530 may have the polarization characteristics, described above with reference to FIG. 2. The barrier dielectric layer 1510 may have the polarization characteristics, illustrated in FIG. 3, through bonding with the gate dielectric layer 1530. In an embodiment, the thickness of the barrier dielectric layer 1510 may be 5 nm or less, and the thickness of the barrier dielectric layer 1510 may be substantially the same as or thinner than the thickness of the gate dielectric layer 1530. In this case, when the thickness ratio between the barrier dielectric layer 1510 and the gate dielectric layer 1530 is distributed within a predetermined range, the barrier dielectric layer 1510 may have ferroelectric polarization characteristics in line with the graph of FIG. 3 rather than the graph of FIG. 1. In addition, the gate dielectric structure G14, including the barrier dielectric layer 1510 and the gate dielectric layer 1530, connected in series to each other with a thickness ratio within the predetermined range, may have the non-ferroelectricity, described above with reference to FIG. 4. The material composition of the barrier dielectric layer 1510 and the gate dielectric layer 1530 may be substantially the same as the material composition of the barrier dielectric layer 1010 and the gate dielectric layer 1030 of the semiconductor device 9, described above with reference to FIG. 23.

The gate electrode 1550 may be disposed on the gate dielectric structure G14. The gate electrode 1550 may include an upper electrode layer 1550U and a lower electrode layer 1550L. The upper electrode layer 1550U and the lower electrode layer 1550L may be electrically connected to each other and may simultaneously control the channel region 1520c. Accordingly, when a gate voltage that is equal to or greater than a threshold voltage is applied to the upper electrode layer 1550U and the lower electrode layer 1550L, a pair of conductive channels may be formed in the channel region 1520c. The material composition of the upper electrode layer 1550U and the lower electrode layer 1550U may be substantially the same as the material composition of the gate electrode 1050 of the semiconductor device 9, described above with reference to FIG. 23.

In some embodiments, the gate dielectric structure G14 may be disposed on only one of the upper surface and lower surface of the active layer 1520. Accordingly, as the gate electrode 1550, only one of the upper electrode layer and the lower electrode layer may be disposed on the gate dielectric structure G14.

Referring to FIGS. 28A to 28C, the source region 1520a of the active layer 1520 may be electrically connected to the bit line 1503. The bit line 1503 may extend in a direction (e.g., the z-direction) that is substantially perpendicular to the surface 1501S of the base structure 1501. The bit line 1503 may include a conductive pillar structure. Meanwhile, the drain region 1520b of the active layer 1520 may be electrically connected to the storage node electrode 1610 of the capacitor Cs.

The storage node electrode 1610 of the capacitor Cs may have a cylindrical shape. The information storage dielectric layer 1620 may be disposed on the storage node electrode 1610. The plate electrode 1630 may be disposed to cover the information storage dielectric layer 1620. Each of the storage node electrode layer 1610 and the plate electrode 1630 may include a conductive material. The information storage dielectric layer 1620 may include oxide, nitride, oxynitride, or a combination of two or more thereof.

In an embodiment, the configurations of the storage node electrode 1610, the information storage dielectric layer 1620, and the plate electrode 1630 of the capacitor Cs may be substantially the same as the configurations of the storage node electrode 410c, the dielectric structure 2003, and the plate electrode 440c of the semiconductor device 404, described above with reference to FIGS. 18A and 18B. That is, the information storage dielectric layer 1620 may include a capacitor dielectric layer and a barrier dielectric layer that are connected in series to each other. In this case, the capacitor dielectric layer may include a non-ferroelectric material, and the barrier dielectric layer may include a ferroelectric material.

In some embodiments not illustrated, the configuration of the storage node electrode 1610, the information storage dielectric layer 1620, and the plate electrode 1630 of the capacitor Cs may be substantially the same as the configuration of the storage node electrode 410a, the dielectric structure 2001, and the plate electrode 440a of the semiconductor device 404, described above with reference to FIGS. 15A and 15B. In this case, the storage node electrode 1610 may have a pillar shape. In some embodiments, the configurations of the storage node electrode 1610, the information storage dielectric layer 1620, and the plate electrode 1630 of the capacitor Cs may be substantially the same as the configurations of the storage node electrode 410b, the dielectric structure 2002, and the plate electrode 440b of the semiconductor device 403 described with reference to FIGS. 17A and 17B. In this case, the storage node electrode 1610 may have a pillar shape including the filling structure 460. In some embodiments, the configurations of the storage node electrode 1610, the information storage dielectric layer 1620, and the plate electrode 1630 of the capacitor Cs may be substantially the same as those of the storage node electrode 410d, the dielectric structure 2004, and the plate electrode 440d of the semiconductor device 406 described with reference to FIGS. 20A and 20B. In this case, the storage node electrode 1610 may have a shape in which a pillar shape and a cylinder shape are combined.

Concepts have been disclosed in conjunction with some embodiments as described above. Those skilled in the art will appreciate that various modifications, additions, and substitutions are possible, without departing from the scope and spirit of the present disclosure. Accordingly, the embodiments disclosed in the present specification should be considered from not a restrictive standpoint but rather from an illustrative standpoint. The scope of the concepts is not limited to the above descriptions but defined by the accompanying claims, and all of distinctive features in the equivalent scope should be construed as being included in the concepts.

What is claimed is:

1. A semiconductor device comprising:
a substrate including a channel region;
a gate dielectric structure disposed over the channel region, the gate dielectric structure including a barrier dielectric layer and a gate dielectric layer that are connected in series to each other; and
a gate electrode disposed over the gate dielectric structure,
wherein the barrier dielectric layer includes a ferroelectric material,
wherein the gate dielectric layer includes a non-ferroelectric material, and
wherein the gate dielectric structure exhibits non-ferroelectric property.

2. The semiconductor device of claim 1, wherein a capacitance of the gate dielectric structure is substantially the same as a capacitance of the gate dielectric layer.

3. The semiconductor device of claim 1, wherein each of the barrier dielectric layer and the gate dielectric layer is an epi-growth layer.

4. The semiconductor device of claim 1, wherein the barrier dielectric layer includes hafnium zirconium oxide.

5. The semiconductor device of claim 1,
wherein the barrier dielectric layer includes a dopant doped in the hafnium zirconium oxide, and
wherein the dopant may include at least one selected from the group consisting of carbon (C), silicon (Si), magnesium (Mg), aluminum (Al), yttrium (Y), nitrogen (N), germanium (Ge), tin (Sn), strontium (Sr), lead (Pb), calcium (Ca), barium (Ba), titanium (Ti), gadolinium (Gd), and lanthanum (La).

6. The semiconductor device of claim 1, wherein the gate dielectric layer includes at least one of hafnium oxide and zirconium oxide.

7. The semiconductor device of claim 1,
wherein the barrier dielectric layer has a crystal structure of an orthorhombic crystal system, and
wherein the gate dielectric layer has a crystal structure of a monoclinic crystal system or a tetragonal crystal system.

8. The semiconductor device of claim 1, further comprising a source region and a drain region that are respectively located at opposite sides of the channel region.

9. The semiconductor device of claim 1, wherein the gate dielectric structure and the gate electrode are disposed over the substrate.

10. The semiconductor device of claim 1, wherein at least a portion of each of the gate dielectric structure and the gate electrode is respectively disposed in a recess region of the substrate.

11. The semiconductor device of claim 10, wherein upper surfaces of the gate dielectric structure and the gate electrode are positioned at a lower level than an upper surface of the substrate.

12. The semiconductor device of claim 10, wherein the barrier dielectric layer is disposed closer to the channel region than the gate dielectric layer.

13. A semiconductor device comprising:
a substrate;
an active layer disposed over the substrate;
a gate dielectric structure disposed to be adjacent to the active layer, the gate dielectric structure including a barrier dielectric layer and a gate dielectric layer that are connected in series to each other; and
a gate electrode disposed over the gate dielectric structure,
wherein the barrier dielectric layer includes a ferroelectric material, and
wherein the gate dielectric layer includes a non-ferroelectric material.

14. The semiconductor device of claim 13, wherein a capacitance of the dielectric structure is substantially the same as a capacitance of the gate dielectric layer.

15. The semiconductor device of claim 13, wherein each of the barrier dielectric layer and the gate dielectric layer is an epi-growth layer.

16. The semiconductor device of claim 13, wherein the active layer has a form of a fin structure that is disposed over the substrate.

17. The semiconductor device of claim 16, further comprising a source region and a drain region that are respectively disposed at opposite edge portions of the active layer in a direction that is parallel to the surface of the substrate.

18. The semiconductor device of claim 17, further comprising a channel region disposed between the source region and the drain region.

19. The semiconductor device of claim 13, wherein the active layer has a form of a pillar structure, extending in a direction that is substantially perpendicular to the surface of the substrate.

20. The semiconductor device of claim 19, wherein the active layer includes a channel region extending in a direction that is substantially perpendicular to the surface of the substrate in the pillar structure.
